(19) United States
(12) Patent Application Publication
(10) Pub. No.: US 2007/0134512 A1
(43) Pub. Date: Jun. 14, 2007

(54) Electroluminescent device containing an anthracene derivative

(75) Inventors: Kevin P. Klubek, West Henrietta, NY (US); Liang-Sheng Liao, Rochester, NY (US); Viktor V. Jarikov, Rochester, NY (US)

Correspondence Address: Paul A. Leipold;Patent Legal Staff, Eastman Kodak Company, 343 State Street, Rochester, NY, 14650-2201, US

(73) Assignee: Eastman Kodak Company

(21) Appl. No.: 11/301,458

(22) Filed: Dec. 13, 2005

(51) Int. Cl. H01L 51/54

(52) U.S. Cl. 428/690; 428/917; 428/212; 313/504; 313/506; 257/E51.051; 257/E51.049

(57) ABSTRACT

An OLED device comprises a cathode, an anode, and located therebetween a light emitting layer, the device comprising a further layer between the light-emitting layer and the anode but not contiguous to the light-emitting layer, the further layer containing a 2,6-diamino-substituted anthracene compound and containing a larger volume percentage of the 2,6-diamino-substituted anthracene compound than the layer contiguous to the light-emitting layer on the anode side.

### FIELD OF THE INVENTION

This invention relates to organic electroluminescent devices. More specifically, this invention relates to devices that emit light from a current-conducting organic layer and include a further layer, not contiguous to the light-emitting layer, containing an anthracene derivative.

### BACKGROUND OF THE INVENTION

While organic electroluminescent (EL) devices have been known for over two decades, their performance limitations have represented a barrier to many desirable applications. In simplest form, an organic EL device is comprised of an anode for hole injection, a cathode for electron injection, and an organic medium sandwiched between these electrodes to support charge recombination that yields emission of light. These devices are also commonly referred to as organic light-emitting diodes, or OLEDs. Representative of earlier organic EL devices are Gurnee et al. U.S. Pat. No. 3,172,862, issued Mar. 9, 1965; Gurnee U.S. Pat. No. 3,173,050, issued Mar. 9, 1965; Dresner, “Double Injection Electroluminescence in Anthracene”, RCA Review, 30, 322, (1969); and Dresner U.S. Pat. No. 3,710,167, issued Jan. 9, 1973. The organic layers in these devices, usually composed of a polycyclic aromatic hydrocarbon, were very thick (much greater than 1 μm). Consequently, operating voltages were very high, often greater than 100V.

More recent organic EL devices include an organic EL element consisting of extremely thin layers (e.g. <1.0 μm) between the anode and the cathode. Herein, the term “organic EL element” encompasses the layers between the anode and cathode. Reducing the thickness lowered the resistance of the organic layers and enabled devices to operate at much lower voltage. In a basic two-layer EL device structure, described first in U.S. Pat. No. 4,356,429, one organic layer of the EL element adjacent to the anode is specifically chosen to transport holes, and therefore is referred to as the hole-transporting layer, and the other organic layer is specifically chosen to transport electrons and is referred to as the electron-transporting layer. Recombination of the injected holes and electrons within the organic EL element results in efficient electroluminescence.

There have also been proposed three-layer organic EL devices that contain an organic light-emitting layer (LEL) between the hole-transporting layer and electron-transporting layer, such as that disclosed by C. Tang et al. (J. Applied Physics, Vol. 65, 3610 (1989)). The light-emitting layer commonly consists of a host material doped with a guest material, otherwise known as a dopant. Still further, there has been proposed in U.S. Pat. No. 4,769,292 a four-layer EL element comprising a hole injecting layer (HIL), a hole-transporting layer (HTL), a light-emitting layer (LEL) and an electron-transporting/injecting layer (ETL). These structures have resulted in improved device efficiency.

Since these early inventions, further improvements in device materials have resulted in improved performance in attributes such as color, stability, luminance efficiency and manufacturability, e.g., as disclosed in U.S. Pat. No. 5,061,569, U.S. Pat. No. 5,409,783, U.S. Pat. No. 5,554,450, U.S. Pat. No. 5,593,788, U.S. Pat. No. 5,683,823, U.S. Pat. No. 5,908,581, U.S. Pat. No. 5,928,802, U.S. Pat. No. 6,020,078, and U.S. Pat. No. 6,208,077, amongst others.

While not always necessary, it is often useful to include a hole-transporting layer in an OLED device. The hole-transporting layer of the organic EL device contains at least one hole-transporting compound such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al U.S. Pat. No. 3,567,450 and U.S. Pat. No. 3,658,520.

A more desirable class of aromatic tertiary amines include at least two aromatic tertiary amine moieties as described in U.S. Pat. No. 4,720,432 and US 5,061,569, U.S. Pat. No. 5,061,569, U.S. Pat. No. 6,074,734, and U.S. Pat. No. 6,242,115, US 2004/0023060, US 2003/0186077, US 2004/0170863, JP 2004/339134. The use of tertiary amines such as tetrarylbenzidine derivatives as hole-transporting materials is well-known. However, many of these tertiary amines, when used as hole-transporting materials, do not afford the combination of low voltage and high luminance with good stability.

In JP 2004/091334, Akiko et al. describe anthracene materials substituted with phenylene diamine groups in the 2,6 positions as useful hole-transporting materials for EL devices. They provide examples of the use of these materials in a layer adjacent to a light-emitting layer. However, such materials can have very low oxidation potentials and may result in unstable devices.

Toshio, JP 1995/109449 provides examples of anthracene-type materials substituted with tertiary amine groups and their use either in the light-emitting layer or adjacent to the light-emitting layer. Akiko et al., JP 2003/146951, describe anthracene materials substituted with tertiary amine groups in the 2,6 positions as useful hole-transporting materials for EL devices and provide examples of their use in a layer adjacent to the LEL.

Hosokawa and co-workers, in US 2003/0072966 and US 2005/0038296, also describe certain tertiary amino-anthracene compounds for use in OLED devices. In particular the materials are described as useful as dopants in the light-emitting layer.

In advanced OLED structures, in addition to a hole-transporting layer, it is usually useful to include one or more organic hole-injecting layer(s) (HIL) in the device. The organic hole-injecting layer(s) is disposed between an anode and an organic hole-transporting layer (HTL). The surface of at least one of the hole-injecting layers is in direct contact with the hole-transporting layer. One common material used in hole-injecting layers is m-TDATA (4,4′,4″-tris[(3-methylphenyl)phenylamino]triphenylamine), but the use of this material often results in higher drive voltages and shorter lifetimes than desired.

Thus there remains a need for organic OLED device components that will provide a combination of low voltage and good stability while still providing high luminance.

### SUMMARY OF THE INVENTION

The invention provides an OLED device comprising a cathode, an anode, and located therebetween a light emitting layer, the device comprising a further layer between the light-emitting layer and the anode but not contiguous to the light-emitting layer, the further layer containing a 2,6-diamino-substituted anthracene compound and containing a larger volume percentage of the 2,6-diamino-substituted anthracene compound than the layer contiguous to the light-emitting layer on the anode side.

The device of the invention provides a combination of low voltage and good stability while still providing high luminance.

### BRIEF DESCRIPTION OF THE DRAWINGS

FIG. 1 shows a schematic cross-sectional view of an OLED device that represents one embodiment of the present invention.

FIG. 2 shows a schematic cross-sectional view of a Stacked OLED device that represents another embodiment of the present invention.

### DETAILED DESCRIPTION OF THE INVENTION

The invention provides for an OLED device that includes a cathode, a light-emitting layer, a layer contiguous to the light-emitting layer and an anode. There is located a further layer, containing a 2,6-diamino-substituted anthracene compound, between the light-emitting layer and the anode but not contiguous to the light-emitting layer.

The further layer contains a larger volume percentage of the 2,6-diamino-substituted anthracene compound than the layer contiguous to the light-emitting layer. In one suitable embodiment, the contiguous layer, that is the layer contiguous to the light-emitting layer on the anode side, is substantially free of a 2,6-diamino-substituted anthracene compound. In this case substantially free means that less than 5% and desirably less than 1% of a 2,6-diamino-substituted anthracene compound is present. Desirably the contiguous layer is completely free of a 2,6-diamino-substituted anthracene compound.

In one embodiment, the further layer is a hole-injecting layer and the contiguous layer is a hole-transporting layer. In another embodiment, there is an additional hole-injecting layer between the further layer and the anode.

In another embodiment, the 2,6-diamino-substituted anthracene compound in the further layer is doped with an oxidizing agent possessing strong electron-withdrawing properties. By “strong electron-withdrawing properties” it is meant that the dopant should be able to accept some electronic charge from the host to form a charge-transfer complex with the host. Some non-limiting examples include organic compounds such as 2,3,5,6- tetrafluoro-7,7,8,8-tetracyanoquinodimethane (F 4-TCNQ) and other derivatives of TCNQ, and inorganic oxidizing agents such as iodine, FeCl₃, FeF₃, SbCl₅, and some other metal halides. In one embodiment, the further layer includes a compound of Formula (1) and 7,7,8,8-tetracyanoquinodimethane or a derivative thereof such as 2,3,5,6-tetrafluoro-7,7,8,8-tetracyanoquinodimethane. Desirably, the dopant (oxidizing agent) is present at a level of less than 20% and suitably at a level of 1- 10% of the layer by volume.

In another embodiment the 2,6-diamino-substituted anthracene compound in the further layer has an oxidation potential of 0.8 V vs. SCE or less and suitably an oxidation potential of 0.7 V vs. SCE or less. Desirably the oxidation potential of the 2,6-diamino-substituted anthracene is between 0.60 V and 0.8 V vs. SCE and suitably between 0.65 V and 0.75 V vs. SCE.

Oxidation potentials can be measured by well-known literature procedures, such as cyclic voltammetry (CV) and Osteryoung square-wave voltammtry (SWV). For a review of electrochemical measurements, see J. O. Bockris and A. K. N. Reddy, Modern Electrochemistry, Plenum Press, New York; and A. J. Bard and L. R. Faulkner, Electrochemical Methods, John Wiley & Sons, New York, and references cited therein. Oxidation potentials are always reported versus a reference. In our case, the reference is the saturated calomel electrode (SCE).

In one suitable embodiment, the 2,6-diamino-substituted anthracene compound is substituted in the 9- and 10-positions with independently selected aromatic groups, such as phenyl groups, naphthyl groups, or biphenyl groups. In another embodiment, the 2,6-diamino-substituted anthracene compound includes at least 9 aromatic rings. Desirably, the 2,6-diamino-substituted anthracene compound does not include a phenylene diamine group, since this may result in too low of an oxidation potential.

In one aspect of the invention, the 2,6-diamino-substituted anthracene compound is represented by Formula (1).

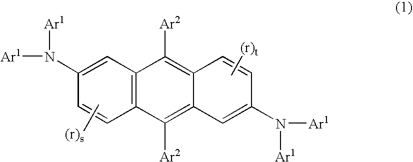

In Formula (1), each Ar¹ may be the same or different and each represents an independently selected aromatic group, such as a phenyl group, a tolyl group, or a naphthyl group. Two adjacent Ar¹ groups may be further linked together to form a ring, for example two adjacent Ar¹ groups may combine to form a five, six or seven member ring.

Each Ar² may be the same or different and each represents an independently selected aromatic group, such as a phenyl group, a tolyl group, or a naphthyl group. Each Ar² may also represent N(Ar³)(Ar³), wherein each Ar3 may be the same or different and each represents an independently selected aromatic group.

In one suitable embodiment, Ar and Ar2 do not contain an aromatic amine. In another embodiment, Ar³ does not include an aromatic amine.

In a further desirable embodiment, each Ar¹ and each Ar² represent an independently selected aryl group.

Each r represents an independently selected substituent, such as a methyl group or a phenyl group. Two adjacent r groups may combine to form a fused ring, such as a fused benzene ring group. In Formula (1), s and t are independently 0-3. In one suitable embodiment, s and t are both 0.

Compounds of Formula (1) can be synthesized by various methods known in the literature. By way of illustration, some materials of Formula (1) can be prepared as shown in Scheme 1, where Ar¹, Ar₂, and Ar₃ represent independently selected aromatic groups. The starting material, 2,6-dibromoanthraquinone can be synthesized according to a literature procedure according to Hodge et al. (Chem. Commun. (Cambridge), 1, 73-74 (1997)). Diaminoanthraquinone derivatives (Int-A, equation A) can be synthesized using palladium catalyzed amination chemistry, which was developed by Hartwig et al. (J. Org. Chem., 64, 5575-80 (1999)). Reaction of (Int-A) with either a grignard reagant or an aryllithiated species will afford the intermediate diol (Int-B, equation B). The crude diol can be reduced using a procedure developed by Smet et al. (Tetrahedron, 55, 7859-74 (1999)) using potassium iodide and sodium hypophosphite hydrate (equation C) to yield 2,6-anthracenediamine derivatives.

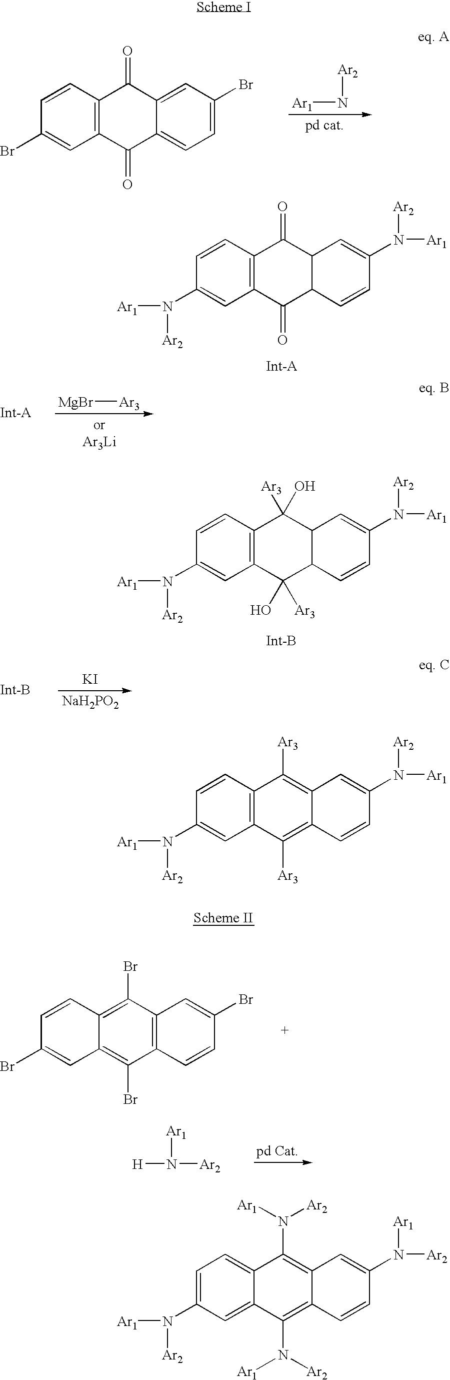

Another route to additional compounds of Formula (1) is depicted in Scheme II. The starting material, 2,6,9,10-tetrabromoanthracene, can be synthesized according to U.S. Pat. No. 4,341,852. Tetraaminoanthracene derivatives can be synthesized using palladium catalyzed amination chemistry (equation D), which was developed by Hartwig et al., J. Org. Chem., 64, 5575-80 (1999).

Illustrative examples of compounds of Formula (1) useful in the present invention are listed below.

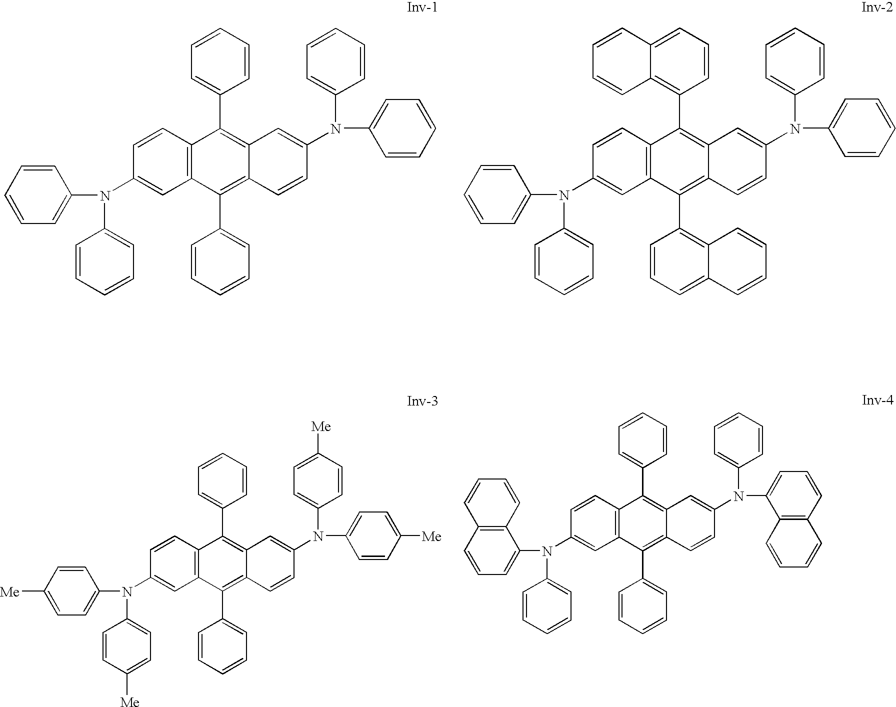

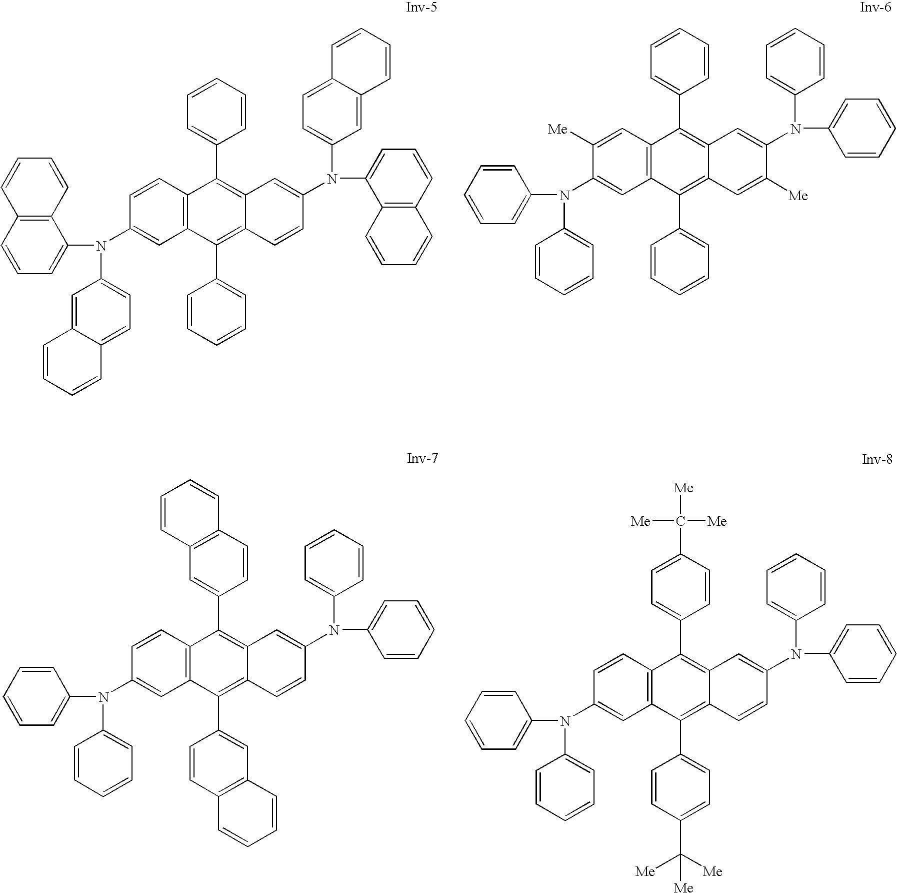

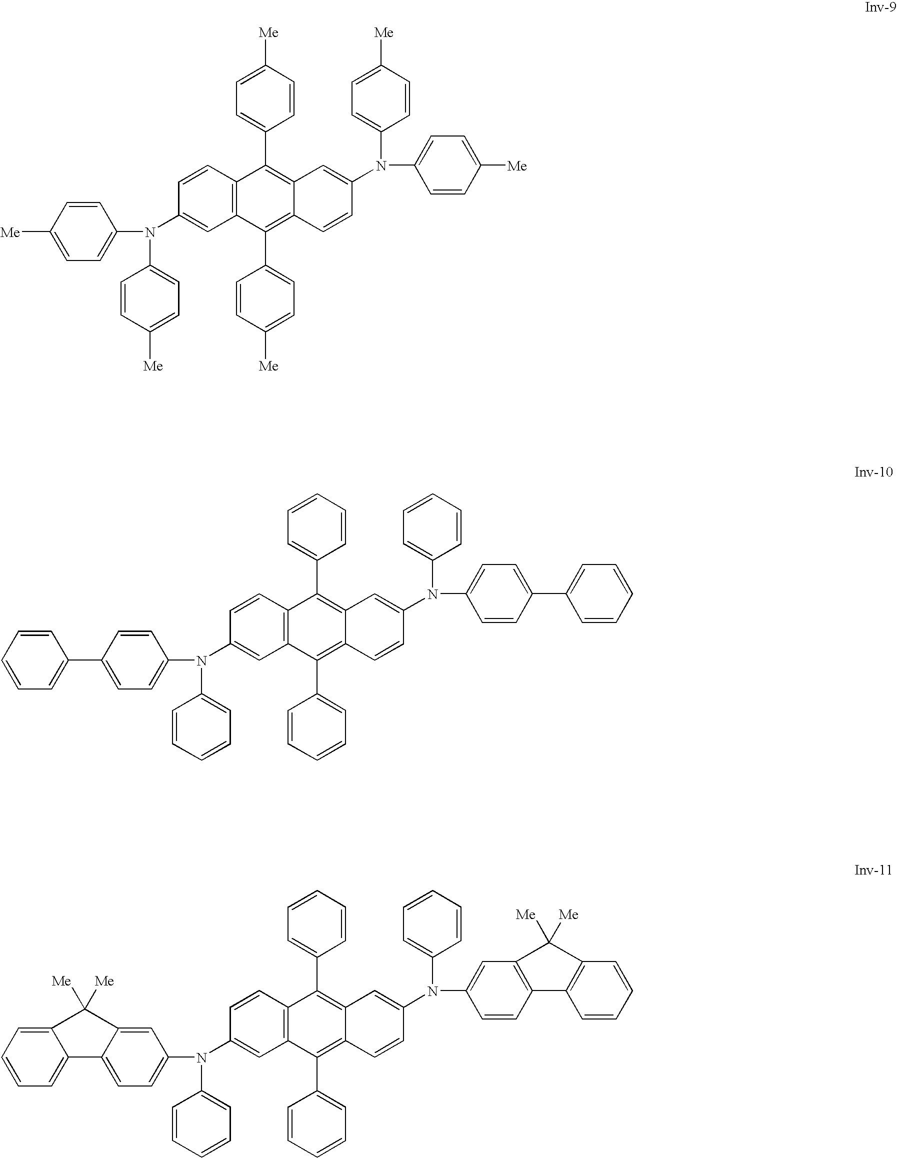

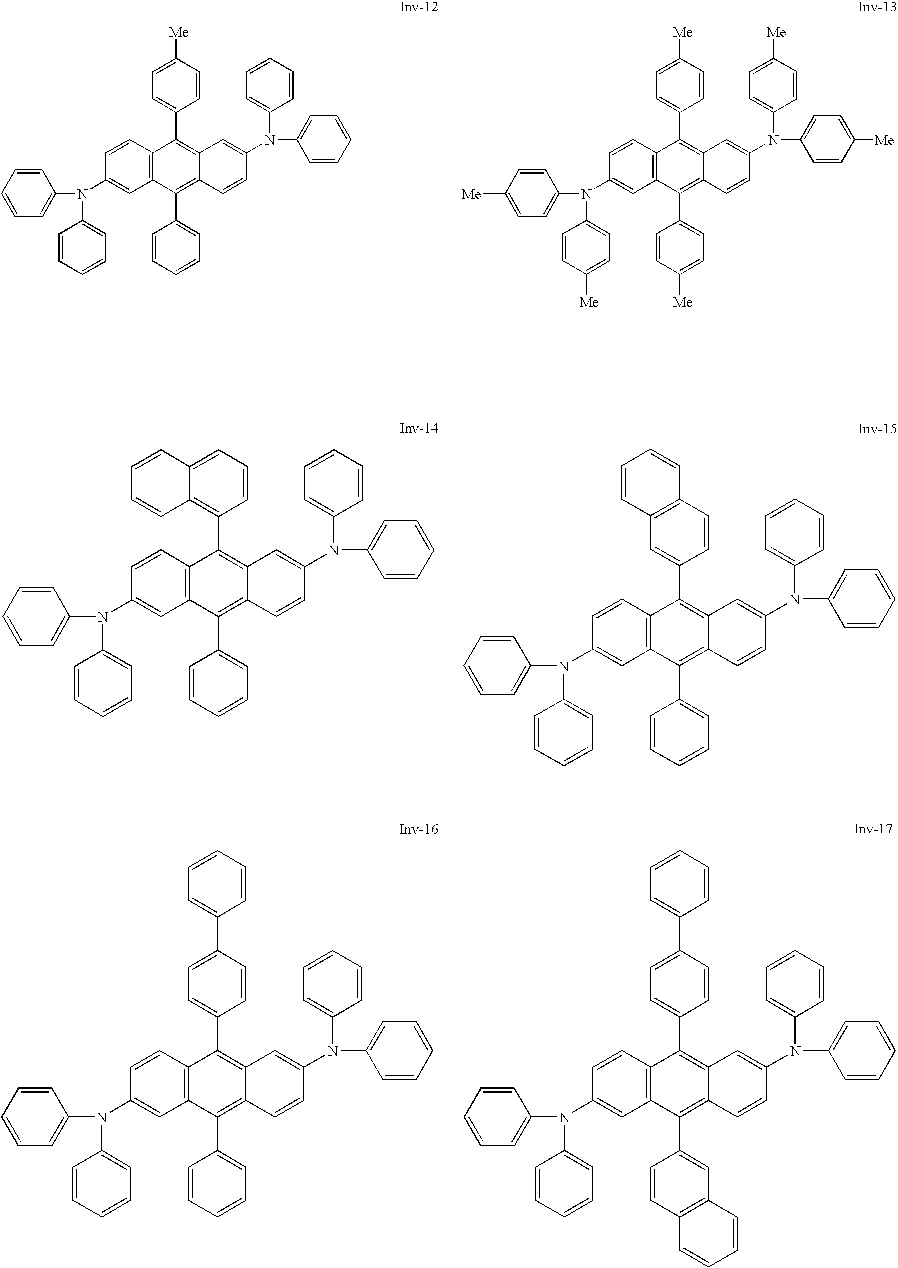

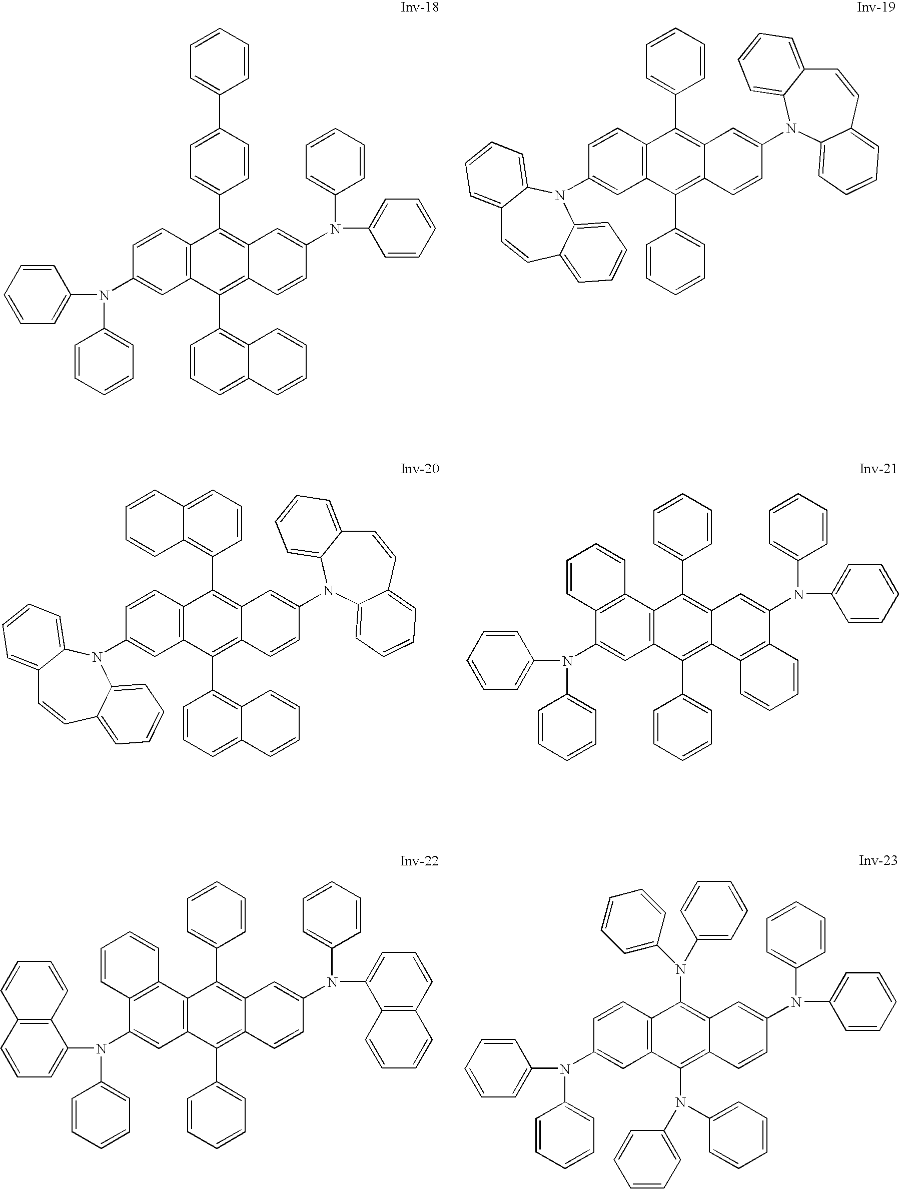

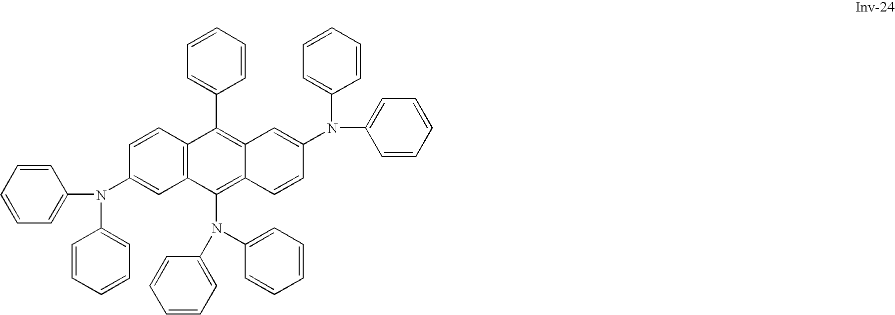

In one aspect of the invention, the layer contiguous to the light-emitting layer on the anode side is referred to as layer L1 and the further layer is referred to as layer L2. L2 is adjacent to L1 on the anode side. Desirably layer L1 includes a triarylamine derivative having an oxidation potential of 0.8-1.1 V vs. SCE and suitably in the range of 0.8-0.9 V. Layer L2 includes a 2,6-diamino-substituted anthracene compound, which has a lower oxidation potential than the triarylamine derivative in layer L1. In one embodiment, the difference in oxidation potential between the triarylamine derivative in L1 and the 2,6-diamino-substituted anthracene compound in L2 is greater than or equal to 0.05 V but less than or equal to 0.4 V. In another embodiment the difference in oxidation potential between the triarylamine derivative in L1 and the 2,6-diamino-substituted anthracene compound in L2 is in the range of 0.1 to 0.3 V.

In one especially suitable embodiment, L1 includes a benzidine derivative. A benzidine compound of the invention consists of a biphenyl moiety, formed by linking two benzene groups, that are substituted in the 4,4′ positions with amino groups. Each amino group is substituted with two, independently selected, aromatic groups.

In one embodiment, the benzidine derivative is represented by Formula (2).

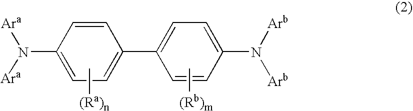

In Formula (2), each Ar^{a} and each Ar^{b} may be the same or different, and each represents an independently selected aromatic group, such as a phenyl group, a 4-tolyl group, a 3-tolyl group, a 1-naphthyl group, or a 2-naphthyl group. In one suitable embodiment, at least one Ar^{a} represents a phenyl group and at least one Ar^{a} represents a naphthyl group. In another desirable embodiment, one Ar^{a}and one Ar^{b} each represent an independently selected phenyl group and one Ar^{a}and one Ar^{b} each represent an independently selected naphthyl group. Two Ar^{a}groups and two Ar^{b} groups may, independently, join together to form additional rings. Each Rₐ and each R_{b} may be the same or different and each represents an independently selected substituent group such as, for example, a methyl group or fluoro group. In Formula (2), n and m are 0-4. In one desirable embodiment, n and m are both 0.

Desirably, each Ar^{a}, Ar^{b}, Rₐ, and R_{b}, as well as n and m, are chosen so that the oxidation potential of the compound of Formula (2) is 0.8-1.1 V vs. SCE. In one suitable embodiment, the oxidation potential is 0.85-0.9 V vs. SCE. Illustrative examples of Formula (2) compounds include those listed below.
HTM-1 NNN,N′-Tetra-p-tolyl-4-4′-dianinobiphenyl
HTM-2 N,N ,N′-Tetraphenyl-4,4′-diaminobiphenyl
HTM-3 4,4′-Bis[N-(1-naphthyl)-N-phenylamino]biphenyl (NPB)
HTM-4 4,4′-Bis[N-(2-naphthyl)-N-phenylamino]biphenyl
HTM-5 4,4′-Bis[N-(3-acenaphthenyl)-N-phenylamino]biphenyl
HTM-6 4,4′-Bis[N-(9-anthryl)-N-phenylamino]biphenyl
HTM-7 4,4″-Bis[N-(1-anthryl)-N-phenylamino]-p-terphenyl
HTM-8 4,4′-Bis[N-(2-phenanthryl)-N-phenylamino]biphenyl
HTM-9 4,4′-Bis[N-(8-fluoranthenyl)-N-phenylamino]biphenyl
HTM-10 4,4′-Bis[N-(2-pyrenyl)-N-phenylamino]biphenyl
HTM-11 4,4′-Bis[N-(2-naphthacenyl)-N-phenylamino]biphenyl
HTM-12 4,4′-Bis[N-(2-perylenyl)-N-phenylamino]biphenyl
HTM-13 4,4′-Bis[N-(1-coronenyl)-N-phenylamino]biphenyl
HTM-14 4,4′-Bis {N-phenyl-N-[4-(1-naphthyl)-phenyl]amino}biphenyl
HTM-15 4,4′-Bis[N-phenyl-N-(2-pyrenyl)amino]biphenyl
HTM-16 4,4′-Bis[N-(3-methylphenyl)-N-phenylamino]biphenyl (TPD).

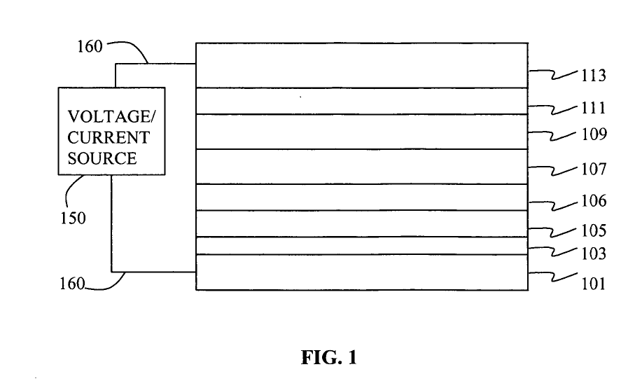

In still a further aspect of the invention, it may be desirable to include a light-emitting material in layer L1. Suitably, the light-emitting material is a fluorescent dopant. For example, it may be desirable to include a yellow-light emitting material in layer L1 (FIG. 1, layer 107) and a blue light-emitting material in the LEL layer (FIG. 1, layer 109) in order to fabricate a device that emits white light.

Examples of useful yellow dopants include 5,6,11,12-tetraphenylnaphthacene (rubrene); 6,11-diphenyl-5,12-bis(4-(6-methyl-benzothiazol-2-yl)phenyl)naphthacene; 5,6,11,12-tetra(2-naphthyl)naphthacene; and

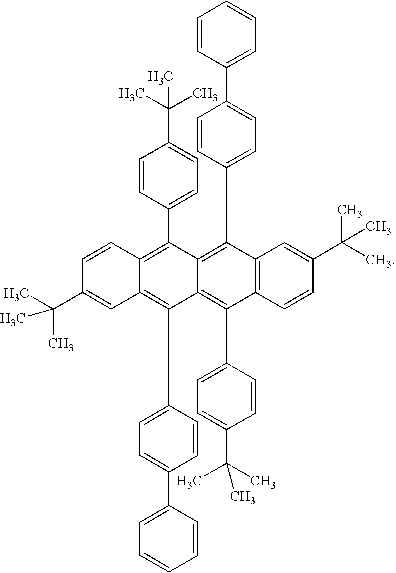

Examples of yellow light-emitting materials also include compounds represented by the following formula:

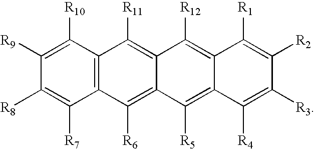

R₁, R₂, R₃, R₄, R₅, R₆, R₇, R₈, R₉, R¹,o R II, and R₁₂ are independently selected as hydrogen or substituent groups. Such substituent groups may join to form further fused rings. In one suitable embodiment, R¹, R₃, R₄, R₇, R₉, R¹⁰, represent hydrogen; R₂ and R₈ represent hydrogen or independently selected alkyl groups; R₅, R₆, R₁₁, and R₁₂ represent independently selected aryl groups.

Many fluorescent materials that emit blue light are known in the art. Particularly useful classes of blue emitters include perylene and its derivatives such as a perylene nucleus bearing one or more substituents such as an alkyl group or an aryl group. A desirable perylene derivative for use as a blue emitting material is 2,5,8,11-tetra-t-butylperylene.

Another useful class of fluorescent materials includes blue-light emitting derivatives of distyrylarenes such as distyrylbenzene and distyrylbiphenyl, including compounds described in U.S. Pat. No. 5,121,029. Among derivatives of distyrylarenes that provide blue luminescence, particularly useful are those substituted with diarylamino groups, also known as distyrylamines. Illustrative examples include those listed below.

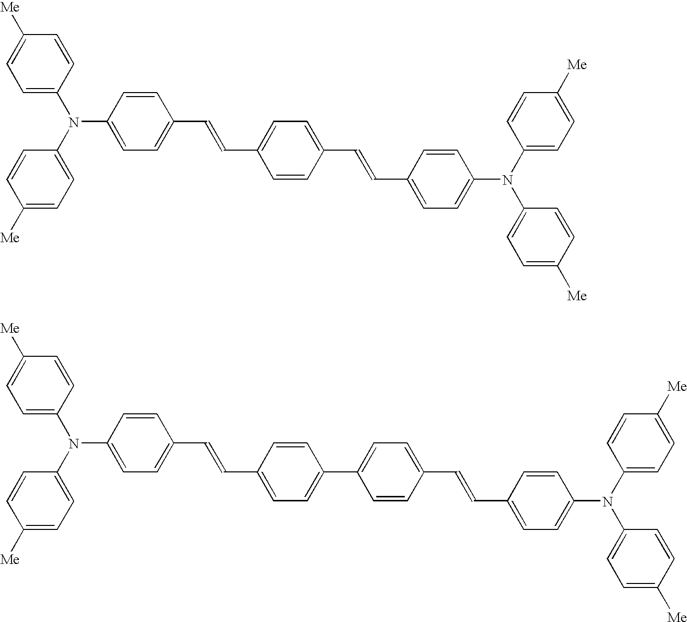

Commonly assigned Ser. No. 10/977,839, filed Oct. 29, 2004 entitled Organic Element for Electroluminescent Devices by Margaret J. Helber, et al., which is incorporated herein by reference, describes additional useful blue light-emitting materials.

Another useful class of blue emitters comprises a boron atom, such as those described in US 2003/0201415. Illustrative examples of useful boron-containing blue fluorescent materials are listed below.

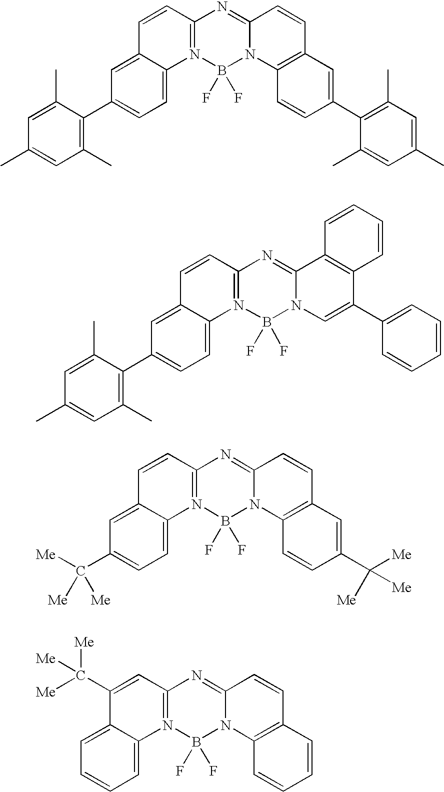

The thickness of layers L1 and L2 are independent of each other and often between 1 and about 200 nm, suitably between 1 and 100 nm, and desirably between 2 and 80 nm.

In another aspect of the invention, the further layer is a hole-injecting layer and the contiguous layer is a hole-transporting layer and there is an additional hole-injecting layer between the further layer and the anode. In one embodiment, this additional hole-injecting layer includes fluorocarbon materials as described in U.S. Pat. No. 6,208,075. In another embodiment, the additional hole-injecting layer includes at least one material selected from those described in U.S. Pat. No. 6,720,573, the disclosures of which are incorporated herein by reference.

Desirably, at least one material included in the additional hole-injecting layer is represented by Formula 3.

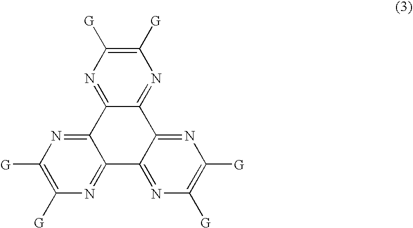

In Formula (3), each G may be the same or different and each represents hydrogen or an independently selected electron withdrawing substituent, provided at least one electron withdrawing substituent is present. In one embodiment, at least one G represents a cyano group. Desirably, each G group is an electron withdrawing substituent, such as a cyano group.

It is well within the skill of the art to determine whether a particular group is electron donating or electron withdrawing. The most common measure of electron donating and withdrawing properties is in terms of Hammett σ values. Hydrogen has a Hammett σ value of zero, while electron donating groups have negative Hammett (y values and electron withdrawing groups have positive Hammett σ values. Lange's handbook of Chemistry, 12^{th} Ed., McGraw Hill, 1979, Table 3-12, pp. 3-134 to 3-138, here incorporated by reference, lists Hammett σ values for a large number of commonly encountered groups. Hammett σ values are assigned based on phenyl ring substitution, but they provide a practical guide for qualitatively selecting electron donating and accepting groups.

Electron withdrawing groups include cyano, amido, sulfonyl, carbonyl, and carbonyloxy substituents. Specific examples include —CN, —F, —CF₃, —NO₂, and —SO₂C₆H₅.

Illustrative examples of materials of Formula (3) are listed below.

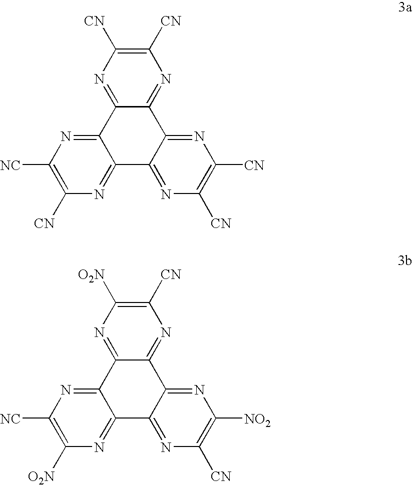

In another aspect of the invention, the inventive device is a stacked OLED that includes at least two light emitting layers. A stacked OLED (also referred to as a cascaded OLED), is fabricated by stacking several individual OLEDs vertically. Stacked OLEDs have been described by Forrest et al. in US 5,703,436, Burrows et al. in U.S. Pat. No. 6,274,980, Tanaka et al. in U.S. Pat. No. 6,107,734, Jones et al. in U.S. Pat. No. 6,337,492, and Liao et al. in U.S. Pat. No. 6,936,961, the disclosures of which are incorporated herein by reference.

In this cascaded device structure only a single external power source is needed to connect to the anode and the cathode with the positive potential applied to the anode and the negative potential to the cathode. With good optical transparency and charge injection, the cascaded device exhibits high electroluminescence efficiency.

This aspect of the invention includes a stacked organic electroluminescent device including an anode, a cathode, and a plurality of organic electroluminescent units disposed between the anode and the cathode. The organic electroluminescent units include at least a hole-transporting layer, an electron-transporting layer, and an electroluminescent zone formed between the hole-transporting layer and the electron-transporting layer. The physical spacing between adjacent electroluminescent zones is desirably more than 90 nm. A connecting unit is disposed between each adjacent organic electroluminescent unit, wherein the connecting unit includes, in sequence, an n-type doped organic layer and a p-type doped organic layer forming a transparent p-n junction structure. At least one n-type doped organic layer comprises a 2,6-diamino-substituted anthracene compound. Desirably the anthracene compound is represented by Formula (1).

In this aspect of the invention, a 2,6-diaminoanthracene compound of the invention, such as a compound represented by Formula (1), is a host material in a p-type doped organic layer in a stacked OLED device. This layer is electrically conductive, and the charge carriers are primarily holes. The conductivity is provided by the formation of a charge-transfer complex as a result of hole-transfer from the p-type dopant to the host material.

Dopants that are p-type dopants are desirably oxidizing agents with strong electron-withdrawing properties. By “strong electron-withdrawing properties” it is meant that the organic dopant should be able to accept some electronic charge from the host to form a charge-transfer complex with the host. Some non-limiting examples include organic compounds such as 2,3,5,6-tetrafluoro-7,7,8,8-tetracyanoquinodimethane (F 4-TCNQ) and other derivatives of TCNQ, and inorganic oxidizing agents such as iodine, FeCl₃, FeF₃, SbCl₅, and some other metal halides. In one embodiment, a layer in the OLED device, such as the p-type connecting layer, includes a compound of Formula (1) and 7,7,8,8-tetracyanoquinodimethane or a derivative thereof such as 2,3,5,6-tetrafluoro-7,7,8,8-tetracyanoquinodimethane. Desirably, the p-type dopant is present at a level of less than 20% and suitably at a level of 1-10% of the layer by volume.

The electron-transporting materials used in conventional OLEDs represent a useful class of host materials for the n-type doped organic layer. Preferred materials are metal chelated oxinoid compounds, including chelates of oxine itself (also commonly referred to as 8-quinolinol or 8-hydroxyquinoline), such as tris(8-hydroxyquinoline) aluminum. Other materials include various butadiene derivatives as disclosed by Tang (U.S. Pat. No. 4,356,429), various heterocyclic optical brighteners as disclosed by Van Slyke et al. (U.S. Pat. No. 4,539,507), triazines, hydroxyquinoline derivatives, and benzazole derivatives. Silole derivatives, such as 2,5-bis(2′,2″-bipridin-6-yl)-1,1-dimethyl-3,4-diphenyl silacyclopentadiene reported by Murata et al. [Applied Physics Letters, 80, 189 (2002)], are also useful host materials.

The materials used as the n-type dopants in the n-type doped organic layer of the connecting units include metals or metal compounds having a work function less than 4.0 eV. Particularly useful dopants include alkali metals, alkali metal compounds, alkaline earth metals, and alkaline earth metal compounds. The term “metal compounds” includes organometallic complexes, metal-organic salts, and inorganic salts, oxides and halides. Among the class of metal-containing n-type dopants, Li, Na, K, R_{b}, Cs, Mg, Ca, Sr, Ba, La, Ce, Sm, Eu, Th, Dy, or Yb, and their inorganic or organic compounds, are particularly useful. The materials used as the n-type dopants in the n-type doped organic layer of the connecting units also include organic reducing agents with strong electron-donating properties. By “strong electron-donating properties” it is meant that the organic dopant should be able to donate at least some electronic charge to the host to form a charge-transfer complex with the host. Non-limiting examples of organic molecules include bis(ethylenedithio)-tetrathiafulvalene (BEDT-TTF), tetrathiafulvalene (TTF), and their derivatives. In the case of polymeric hosts, the dopant can be any of the above or also a material molecularly dispersed or copolymerized with the host as a minor component.

The n-type doped organic layer is adjacent to the ETL of the organic EL unit towards the anode side, and the p-type doped organic layer is adjacent to the HTL of the organic EL unit towards the cathode side. The n-type doped organic layer is selected to provide efficient electron injection into the adjacent electron- transporting layer. The p-type doped organic layer is selected to provide efficient hole-injection into the adjacent hole-transporting layer. Both of the doped layers should have the optical transmission higher than 50%, and desirably higher than 60% in the visible region of the spectrum. In addition, since the connecting units comprise organic materials, their fabrication method can be identical to the fabrication method of the organic EL units. Preferably, a thermal evaporation method is used for the deposition of all the organic materials in the fabrication of the cascaded OLEDs.

Unless otherwise provided, when a group, compound or formula containing a substitutable hydrogen is referred to, it is also intended to encompass not only the unsubstituted form, but also form further substituted with any substituent group or groups as herein mentioned, so long as the substituent does not destroy properties necessary for utility. Additionally, when the term “group” is used, it means that when a substituent group contains a substitutable hydrogen, it is also intended to encompass not only the substituent's unsubstituted form, but also its form further substituted with any substituent group or groups as herein mentioned, so long as the substituent does not destroy properties necessary for device utility. Suitably, a substituent group may be halogen or may be bonded to the remainder of the molecule by an atom of carbon, silicon, oxygen, nitrogen, phosphorous, sulfur, selenium, or boron. The substituent may be, for example, halogen, such as chloro, bromo or fluoro; nitro; hydroxyl; cyano; carboxyl; or groups which may be further substituted, such as alkyl, including straight or branched chain or cyclic alkyl, such as methyl, trifluoromethyl, ethyl, t-butyl, 3-(2,4-di-t-pentylphenoxy) propyl, and tetradecyl; alkenyl, such as ethylene, 2-butene; alkoxy, such as methoxy, ethoxy, propoxy, butoxy, 2-methoxyethoxy, sec-butoxy hexyloxy, 2-ethylhexyloxy, tetradecyloxy, 2-(2,4-di-t-pentylphenoxy)ethoxy, and 2-dodecyloxyethoxy; aryl such as phenyl, 4-t-butylphenyl, 2,4,6-trimethylphenyl, naphthyl; aryloxy, such as phenoxy, 2-methylphenoxy, alpha- or beta-naphthyloxy, and 4-tolyloxy; carbonamido, such as acetamido, benzamido, butyramido, tetradecanamido, alpha-(2,4-di-t-pentyl-phenoxy)acetamido, alpha-(2,4-di-t-pentylphenoxy)butyramido, alpha-(3-pentadecylphenoxy)-hexanamido, alpha-(4-hydroxy-3-t-butylphenoxy)-tetradecanamido, 2-oxo-pyrrolidin-1-yl, 2-oxo-5-tetradecylpyrrolin-1-yl, N-methyltetradecanamido, N-succinimido, N-phthalimido, 2,5-dioxo-1-oxazolidinyl, 3-dodecyl-2,5-dioxo-1-imidazolyl, and N-acetyl-N-dodecylamino, ethoxycarbonylamino, phenoxycarbonylamino, benzyloxycarbonylamino, hexadecyloxycarbonylamino, 2,4-di-t-butylphenoxycarbonylamino, phenylcarbonylamino, 2,5-(di-t-pentylphenyl)carbonylamino, p-dodecyl-phenylcarbonylamino, p-tolylcarbonylamino, N-methylureido, N,N-dimethylureido, N-methyl-N-dodecylureido, N-hexadecylureido, N,N-dioctadecylureido, N,N-dioctyl-N′-ethylureido, N-phenylureido, N,N-diphenylureido, N-phenyl-N-p-tolylureido, N-(m-hexadecylphenyl)ureido, N,N-(2,5-di-t-pentylphenyl)-N′-ethylureido, and t-butylcarbonamido; sulfonamido, such as methylsulfonamido, benzenesulfonamido, p-tolylsulfonamido, p-dodecylbenzenesulfonamido, N-methyltetradecylsulfonamido, N,N-dipropyl-sulfamoylamino, and hexadecylsulfonamido; sulfamoyl, such as N-methylsulfamoyl, N-ethylsulfamoyl, N,N-dipropylsulfamoyl, N-hexadecylsulfamoyl, N,N-dimethylsulfamoyl, N-[3-(dodecyloxy)propyl]sulfamoyl, N-[4-(2,4-di-t-pentylphenoxy)butyl]sulfamoyl, N-methyl-N-tetradecylsulfamoyl, and N-dodecylsulfamoyl; carbamoyl, such as N-methylcarbamoyl, N,N-dibutylcarbamoyl, N-octadecylcarbamoyl, N-[4-(2,4-di-t-pentylphenoxy)butyl]carbamoyl, N-methyl-N-tetradecylcarbamoyl, and N,N-dioctylcarbamoyl; acyl, such as acetyl, (2,4-di-t-amylphenoxy)acetyl, phenoxycarbonyl, p-dodecyloxyphenoxycarbonyl methoxycarbonyl, butoxycarbonyl, tetradecyloxycarbonyl, ethoxycarbonyl, benzyloxycarbonyl, 3-pentadecyloxycarbonyl, and dodecyloxycarbonyl; sulfonyl, such as methoxysulfonyl, octyloxysulfonyl, tetradecyloxysulfonyl, 2-ethylhexyloxysulfonyl, phenoxysulfonyl, 2,4-di-t-pentylphenoxysulfonyl, methylsulfonyl, octylsulfonyl, 2-ethylhexylsulfonyl, dodecylsulfonyl, hexadecylsulfonyl, phenylsulfonyl, 4-nonylphenylsulfonyl, and p-tolylsulfonyl; sulfonyloxy, such as dodecylsulfonyloxy, and hexadecylsulfonyloxy; sulfinyl, such as methylsulfinyl, octylsulfinyl, 2-ethylhexylsulfinyl, dodecylsulfinyl, hexadecylsulfinyl, phenylsulfinyl, 4-nonylphenylsulfinyl, and p-tolylsulfinyl; thio, such as ethylthio, octylthio, benzylthio, tetradecylthio, 2-(2,4-di-t-pentylphenoxy)ethylthio, phenylthio, 2-butoxy-5-t-octylphenylthio, and p-tolylthio; acyloxy, such as acetyloxy, benzoyloxy, octadecanoyloxy, p-dodecylamidobenzoyloxy, N-phenylcarbamoyloxy, N-ethylcarbamoyloxy, and cyclohexylcarbonyloxy; amine, such as phenylanilino, 2-chloroanilino, diethylamine, dodecylamine; imino, such as 1 (N-phenylimido)ethyl, N-succinimido or 3-benzylhydantoinyl; phosphate, such as dimethylphosphate and ethylbutylphosphate; phosphite, such as diethyl and dihexylphosphite; a heterocyclic group, a heterocyclic oxy group or a heterocyclic thio group, each of which may be substituted and which contain a 3 to 7 membered heterocyclic ring composed of carbon atoms and at least one hetero atom selected from the group consisting of oxygen, nitrogen, sulfur, phosphorous, or boron. Such as 2-furyl, 2-thienyl, 2-benzimidazolyloxy or 2-benzothiazolyl; quaternary ammonium, such as triethylammonium; quaternary phosphonium, such as triphenylphosphonium; and silyloxy, such as trimethylsilyloxy.

If desired, the substituents may themselves be further substituted one or more times with the described substituent groups. The particular substituents used may be selected by those skilled in the art to attain desirable properties for a specific application and can include, for example, electron-withdrawing groups, electron-donating groups, and steric groups. When a molecule may have two or more substituents, the substituents may be joined together to form a ring such as a fused ring unless otherwise provided. Generally, the above groups and substituents thereof may include those having up to 48 carbon atoms, typically 1 to 36 carbon atoms and usually less than 24 carbon atoms, but greater numbers are possible depending on the particular substituents selected.

General Device Architecture

The present invention can be employed in many EL device configurations using small molecule materials, oligomeric materials, polymeric materials, or combinations thereof. These include very simple structures comprising a single anode and cathode to more complex devices, such as passive matrix displays comprised of orthogonal arrays of anodes and cathodes to form pixels, and active-matrix displays where each pixel is controlled independently, for example, with thin film transistors (TFTs).

There are numerous configurations of the organic layers wherein the present invention can be successfully practiced. The essential requirements of an OLED are an anode, a cathode, and an organic light-emitting layer located between the anode and cathode. Additional layers may be employed as more fully described hereafter.

A typical structure according to the present invention and especially useful for a small molecule device, is shown in FIG. 1 and is comprised of a substrate 101, an anode 103, a hole-injecting layer 105, a hole-transporting layer 107, a light-emitting layer 109, an electron-transporting layer 111, and a cathode 113. These layers are described in detail below. Note that the substrate 101 may alternatively be located adjacent to the cathode 113, or the substrate 101 may actually constitute the anode 103 or cathode 113. The organic layers between the anode 103 and cathode 113 are conveniently referred to as the organic EL element. Also, the total combined thickness of the organic layers is desirably less than 500 nm. If the device includes phosphorescent material, a hole-blocking layer, located between the light-emitting layer and the electron-transporting layer, may be present.

The anode 103 and cathode 113 of the OLED are connected to a voltage/current source 150 through electrical conductors 160. The OLED is operated by applying a potential between the anode 103 and cathode 113 such that the anode 103 is at a more positive potential than the cathode 113. Holes are injected into the organic EL element from the anode 103 and electrons are injected into the organic EL element at the cathode 113. Enhanced device stability can sometimes be achieved when the OLED is operated in an AC mode where, for some time period in the AC cycle, the potential bias is reversed and no current flows. An example of an AC driven OLED is described in U.S. Pat. No. 5,552,678.

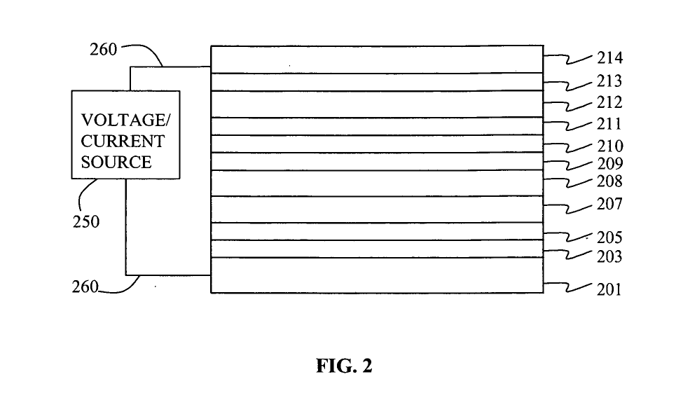

Another useful embodiment of the invention is shown in FIG. 2, which is a schematic of a stacked OLED device. FIG. 2 shows two EL units connected by an n-type doped organic layer, 209, and a p-type doped organic layer, 210. FIG. 2 also shows a substrate, 201, an anode 203, an optional hole-injecting layer 205, a first and second hole-transporting layers 207 and 211, first and second light-emitting layers 208 and 212, and an electron-transporting layer 213. The anode 203 and cathode 214 of the OLED are connected to a voltage/current source 250 through electrical conductors 260. It is also possible to have a stacked OLED device having a plurality of organic EL units and a plurality of organic connectors. In one embodiment of the invention, the p-type organic layer includes a 2,6-diamino-substituted anthracene compound.

Substrate

The OLED device of this invention is typically provided over a supporting substrate 101 where either the cathode 113 or anode 103 can be in contact with the substrate. The electrode in contact with the substrate 101 is conveniently referred to as the bottom electrode. Conventionally, the bottom electrode is the anode 103, but this invention is not limited to that configuration. The substrate 101 can either be light transmissive or opaque, depending on the intended direction of light emission. The light transmissive property is desirable for viewing the EL emission through the substrate 101. Transparent glass or plastic is commonly employed in such cases. The substrate 101 can be a complex structure comprising multiple layers of materials. This is typically the case for active matrix substrates wherein TFTs are provided below the OLED layers. It is still necessary that the substrate 101, at least in the emissive pixelated areas, be comprised of largely transparent materials such as glass or polymers. For applications where the EL emission is viewed through the top electrode, the transmissive characteristic of the bottom support is immaterial, and therefore the substrate can be light transmissive, light absorbing or light reflective. Substrates for use in this case include, but are not limited to, glass, plastic, semiconductor materials such as silicon, ceramics, and circuit board materials. Again, the substrate 101 can be a complex structure comprising multiple layers of materials such as found in active matrix TFT designs. It is necessary to provide in these device configurations a light-transparent top electrode.

Anode

When the desired electroluminescent light emission (EL) is viewed through the anode, the anode 103 should be transparent or substantially transparent to the emission of interest. Common transparent anode materials used in this invention are indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used as the anode 103. For applications where EL emission is viewed only through the cathode 113, the transmissive characteristics of the anode 103 are immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable means such as evaporation, sputtering, chemical vapor deposition, or electrochemical means. Anodes can be patterned using well-known photolithographic processes. Optionally, anodes may be polished prior to application of other layers to reduce surface roughness so as to minimize short circuits or enhance reflectivity.

Cathode

When light emission is viewed solely through the anode 103, the cathode 113 used in this invention can be comprised of nearly any conductive material. Desirable materials have good film-forming properties to ensure good contact with the underlying organic layer, promote electron injection at low voltage, and have good stability. Useful cathode materials often contain a low work function metal (<4.0 eV) or metal alloy. One useful cathode material is comprised of a Mg:Ag alloy wherein the percentage of silver is in the range of 1 to 20%, as described in U.S. Pat. No. 4,885,221. Another suitable class of cathode materials includes bilayers comprising the cathode and a thin electron-injection layer (EIL) in contact with an organic layer (e.g., an electron transporting layer (ETL)), the cathode being capped with a thicker layer of a conductive metal. Here, the EIL preferably includes a low work function metal or metal salt, and if so, the thicker capping layer does not need to have a low work function. One such cathode is comprised of a thin layer of LiF followed by a thicker layer of Al or Ag as described in U.S. Pat. No. 5,677,572. An ETL material doped with an alkali metal, for example, Li-doped Alq, is another example of a useful EIL. Other useful cathode material sets include, but are not limited to, those disclosed in U.S. Pat. Nos. 5,059,861, 5,059,862, and 6,140,763.

When light emission is viewed through the cathode, the cathode 113 must be transparent or nearly transparent. For such applications, metals must be thin or one must use transparent conductive oxides, or a combination of these materials. Optically transparent cathodes have been described in more detail in U.S. Pat. No. 4,885,211, U.S. Pat. No. 5,247,190, JP 3,234,963, U.S. Pat. No. 5,703,436, U.S. Pat. No. 5,608,287, U.S. Pat. No. 5,837,391, U.S. Pat. No. 5,677,572, U.S. Pat. No. 5,776,622, U.S. Pat. No. 5,776,623, U.S. Pat. No. 5,714,838, U.S. Pat. No. 5,969,474, U.S. Pat. No. 5,739,545, U.S. Pat. No. 5,981,306, U.S. Pat. No. 6,137,223, U.S. Pat. No. 6,140,763, U.S. Pat. No. 6,172,459, EP 1076 368, U.S. Pat. No. 6,278,236, and U.S. Pat. No. 6,284,3936. Cathode materials are typically deposited by any suitable method such as evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

Hole-Injecting Layer (HIL)

An optional first hole-injecting layer,105, may be provided between anode 103 and hole-injecting layer 106. The first hole-injecting layer can serve to improve the film formation property of subsequent organic layers and to facilitate injection of holes into layer 106. Suitable materials for use in the first hole-injecting layer 105 include, but are not limited to, porphyrinic compounds as described in U.S. Pat. No. 4,720,432, plasma-deposited fluorocarbon polymers as described in U.S. Pat. No. 6,208,075, and some aromatic amines, for example, MTDATA (4,4′,4″-tris[(3-methylphenyl)phenylamino]triphenylamine). Alternative hole-injecting materials reportedly useful in organic EL devices are described in EP 0 891 121 A1 and EP 1029 909 A1. A first hole-injection layer is conveniently used in the present invention, and is desirably a plasma-deposited fluorocarbon polymer. The thickness of a first hole-injection layer containing a plasma-deposited fluorocarbon polymer can be in the range of 0.2 nm to 15 nm and suitably in the range of 0.3 to 1.5 nm.

A hole-injecting layer, corresponding to 106 in FIG. 1 and also referred to as L2 is present. This layer has been discussed in detail previously.

Hole-Transporting Layer (HTL)

Layer 107, also referred to as L1, has already been described. However additional layers of hole-transporting materials, such as aromatic tertiary amine materials may be present in some embodiments. An aromatic tertiary amine is understood to be a compound containing at least one trivalent nitrogen atom that is bonded only to carbon atoms, at least one of which is a member of an aromatic ring. Desirably the trivalent nitrogen atom is sp³ hybridized. In one form the aromatic tertiary amine can be an arylamine, such as a monoarylamine, diarylamine, triarylamine, or a polymeric arylamine. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al U.S. Pat. No. 3,567,450 and U.S. Pat. No. 3,658,520 and in Kawamura et al. U.S. Pat. No. 6,074,734.

A more preferred class of aromatic tertiary amines are those which include at least two aromatic tertiary amine moieties as described in U.S. Pat. No. 4,720,432 and U.S. Pat. No. 5,061,569. Such compounds include those represented by structural formula (A). 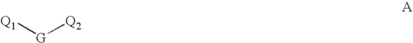
wherein Q₁ and Q₂ are independently selected aromatic tertiary amine moieties and G is a linking group such as an arylene, cycloalkylene, or alkylene group of a carbon to carbon bond. In one embodiment, at least one of Q₁ or Q₂ contains a polycyclic fused ring structure, e.g., a naphthalene. When G is an aryl group, it is conveniently a phenylene, biphenylene, or naphthalenediyl moiety.

A useful class of triarylamines satisfying structural formula (A) and containing two triarylamine moieties is represented by structural formula (B): 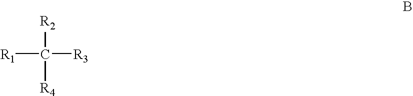
where

R₁ and R₂ each independently represents a hydrogen atom, an aryl group, or an alkyl group or R₁ and R₂ together represent the atoms completing a cycloalkyl group; and

R₃ and R₄ each independently represents an aryl group, which is in turn substituted with a diaryl substituted amino group, as indicated by structural formula (C):

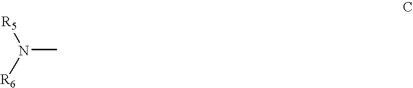

wherein R₅ and R₆ are independently selected aryl groups. In one embodiment, at least one of R₅ or R₆ contains a polycyclic fused ring structure, e.g., a naphthalene.

Another class of aromatic tertiary amines is the tetraaryldiamines. Desirable tetraaryldiamines include two diarylamino groups, such as indicated by formula (C), linked through an arylene group. Useful tetraaryldiamines include those represented by formula (D). 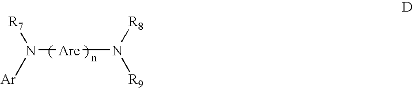
wherein
each Are is an independently selected arylene group, such as a phenylene, naphthalenediyl or anthracenediyl moiety,
n is an integer of from 1 to 4, and
Ar, R₇, R₈, and R₉ are independently selected aryl groups.

In a typical embodiment, at least one of Ar, R₇, R₈, and R₉ is a polycyclic fused ring structure, e.g., a naphthalene.

The various alkyl, alkylene, aryl, and arylene moieties of the foregoing structural formulae (A), (B), (C), (D), can each in turn be substituted. Typical substituents include alkyl groups, alkoxy groups, aryl groups, aryloxy, benzo groups. The various alkyl and alkylene moieties typically contain from about 1 to 6 carbon atoms. The cycloalkyl moieties can contain from 3 to about 10 carbon atoms, but typically contain five, six, or seven ring carbon atoms—e.g., cyclopentyl, cyclohexyl, and cycloheptyl ring structures. The aryl and arylene moieties are usually phenyl and phenylene moieties.

The hole-transporting layer can be formed of a single tertiary amine compound or a mixture of such compounds. Specifically, one may employ a triarylamine, such as a triarylamine satisfying the formula (B), in combination with a tetraaryldiamine, such as indicated by formula (D). Illustrative of useful aromatic tertiary amines are the following:
1,1-Bis(4-di-p-tolylaminophenyl)cyclohexane (TAPC)
1,1-Bis(4-di-p-tolylaminophenyl)-4-methylcyclohexane
1,1-Bis(4-di-p-tolylaminophenyl)-4-phenylcyclohexane
1,1-Bis(4-di-p-tolylaminophenyl)-3-phenylpropane (TAPPP)
N,N,N′,N′-tetraphenyl-4,4′″-diamino-1,1′:4′,1″:4″,1′″-quaterphenyl
Bis(4-dimethylamino-2-methylphenyl)phenylmethane
1,4-bis[2-[4-[N,N-di(p-toly)amino]phenyl]vinyl]benzene (BDTAPVB)
N,N,N′,N′-Tetra-p-tolyl-4,4′-diaminobiphenyl (TTB)
N,N,N′,N′-Tetraphenyl-4,4′-diaminobiphenyl
N,N,N′,N′-tetra-1-naphthyl-4,4′-diaminobiphenyl
N,N,N′,N′-tetra-2-naphthyl-4,4′-diaminobiphenyl
N-Phenylcarbazole
4,4′-Bis[N-(1-naphthyl)-N-phenylamino]biphenyl (NPB)
4,4′-Bis[N-(1-naphthyl)-N-(2-naphthyl)amino]biphenyl (TNB)
4,4′-Bis[N-(1-naphthyl)-N-phenylamino]p-terphenyl
4,4′-Bis[N-(2-naphthyl)-N-phenylamino]biphenyl
4,4′-Bis[N-(3-acenaphthenyl)-N-phenylamino]biphenyl
1,5-Bis[N-(1-naphthyl)-N-phenylamino]naphthalene
4,4′-Bis[N-(9-anthryl)-N-phenylamino]biphenyl
4,4′-Bis[N-(1-anthryl)-N-phenylamino]-p-terphenyl
4,4′-Bis[N-(2-phenanthryl)-N-phenylamino]biphenyl
4,4′-Bis[N-(8-fluoranthenyl)-N-phenylamino]biphenyl
4,4′-Bis[N-(2-pyrenyl)-N-phenylamino]biphenyl
4,4′-Bis[N-(2-naphthacenyl)-N-phenylamino]biphenyl
4,4′-Bis[N-(2-perylenyl)-N-phenylamino]biphenyl
4,4′-Bis[N-(1-coronenyl)-N-phenylamino]biphenyl
2,6-Bis(di-p-tolylamino)naphthalene
2,6-Bis[di-(1-naphthyl)amino]naphthalene
2,6-Bis[N-(1-naphthyl)-N-(2-naphthyl)amino]naphthalene
N,N,N′,N′-Tetra(2-naphthyl)-4,4″-diamino-p-terphenyl
4,4′-Bis {N-phenyl-N-[4-(1-naphthyl)-phenyl]amino}biphenyl
2,6-Bis[N,N-di(2-naphthyl)amino]fluorene
4,4′,4″-tris[(3-methylphenyl)phenylamino]triphenylamine (MTDATA)
4,4′-Bis[N-(3-methylphenyl)-N-phenylamino]biphenyl (TPD)

Another class of useful hole-transporting materials includes polycyclic aromatic compounds as described in EP 1009 041. Tertiary aromatic amines with more than two amine groups may be used including oligomeric materials. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS. It is also possible for the hole-transporting layer to comprise two or more sublayers of differing compositions, the composition of each sublayer being as described above. The thickness of the hole-transporting layer can be between 10 and about 500 nm and suitably between 50 and 300 nm.

Lipht-Emitting Layer (LEL)

As more fully described in U.S. Pat. Nos. 4,769,292 and 5,935,721, the light-emitting layer (LEL) of the organic EL element includes a luminescent material where electroluminescence is produced as a result of electron-hole pair recombination. The light-emitting layer can be comprised of a single material, but more commonly consists of a host material doped with a guest emitting material or materials where light emission comes primarily from the emitting materials and can be of any color. The host materials in the light-emitting layer can be an electron-transporting material, as defined below, a hole-transporting material, as defined above, or another material or combination of materials that support hole-electron recombination. Fluorescent emitting materials are typically incorporated at 0.01 to 10% by weight of the host material.

The host and emitting materials can be small non-polymeric molecules or polymeric materials such as polyfluorenes and polyvinylarylenes (e.g., poly(p-phenylenevinylene), PPV). In the case of polymers, small-molecule emitting materials can be molecularly dispersed into a polymeric host, or the emitting materials can be added by copolymerizing a minor constituent into a host polymer. Host materials may be mixed together in order to improve film formation, electrical properties, light emission efficiency, operating lifetime, or manufacturability. The host may comprise a material that has good hole-transporting properties and a material that has good electron-transporting properties.

An important relationship for choosing a fluorescent material as a guest emitting material is a comparison of the excited singlet-state energies of the host and the fluorescent material. It is highly desirable that the excited singlet-state energy of the fluorescent material be lower than that of the host material. The excited singlet-state energy is defined as the difference in energy between the emitting singlet state and the ground state. For non-emissive hosts, the lowest excited state of the same electronic spin as the ground state is considered the emitting state.

Host and emitting materials known to be of use include, but are not limited to, those disclosed in U.S. Pat. No. 4,768,292, U.S. Pat. No. 5,141,671, U.S. Pat. No. 5,150,006, U.S. Pat. No. 5,151,629, U.S. Pat. No. 5,405,709, U.S. Pat. No. 5,484,922, U.S. Pat. No. 5,593,788, U.S. Pat. No. 5,645,948, U.S. Pat. No. 5,683,823, U.S. Pat. No. 5,755,999, U.S. Pat. No. 5,928,802, U.S. Pat. No. 5,935,720, U.S. Pat. No. 5,935,721, and U.S. Pat. No. 6,020,078.

Metal complexes of 8-hydroxyquinoline and similar derivatives, also known as metal-chelated oxinoid compounds (Formula E), constitute one class of useful host compounds capable of supporting electroluminescence, and are particularly suitable for light emission of wavelengths longer than 500 nm, e.g., green, yellow, orange, and red. 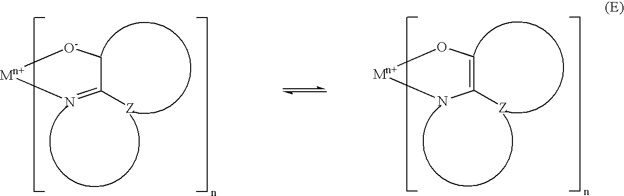
wherein
M represents a metal;
n is an integer of from 1 to 4; and
Z independently in each occurrence represents the atoms completing a nucleus having at least two fused aromatic rings.

From the foregoing it is apparent that the metal can be monovalent, divalent, trivalent, or tetravalent metal. The metal can, for example, be an alkali metal, such as lithium, sodium, or potassium; an alkaline earth metal, such as magnesium or calcium; a trivalent metal, such aluminum or gallium, or another metal such as zinc or zirconium. Generally any monovalent, divalent, trivalent, or tetravalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is usually maintained at 18 or less.

Illustrative of useful chelated oxinoid compounds are the following:
CO-1: Aluminum trisoxine [alias, tris(8-quinolinolato)aluminum(III)]
CO-2: Magnesium bisoxine [alias, bis(8-quinolinolato)magnesium(II)]
CO-3: Bis[benzo{f}-8-quinolinolato]zinc (II)
CO-4: Bis(2-methyl-8-quinolinolato)aluminum(III)-□-oxo-bis(2-methyl-8-quinolinolato) aluminum(III)
CO-5: Indium trisoxine [alias, tris(8-quinolinolato)indium]
CO-6: Aluminum tris(5-methyloxine) [alias, tris(5-methyl-8-quinolinolato)aluminum(III)]
CO-7: Lithium oxine [alias, (8-quinolinolato)lithium(I)]
CO-8: Gallium oxine [alias, tris(8-quinolinolato)gallium(III)]
CO-9: Zirconium oxine [alias, tetra(8-quinolinolato)zirconium(IV)]

ivatives of 9,10-di-(2-naphthyl)anthracene (Formula F) constitute one class of useful host materials capable of supporting electroluminescence, and are particularly suitable for light emission of wavelengths longer than 400 nm, e.g., blue, green, yellow, orange or red. 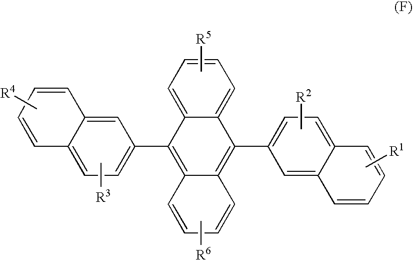
wherein: R′, R₂, R₃, R₄, R₅, and R₆ represent one or more substituents on each ring where each substituent is individually selected from the following groups:
Group 1: hydrogen, or alkyl of from 1 to 24 carbon atoms;
Group 2: aryl or substituted aryl of from 5 to 20 carbon atoms;
Group 3: carbon atoms from 4 to 24 necessary to complete a fused aromatic ring of anthracenyl; pyrenyl, or perylenyl;
Group 4: heteroaryl or substituted heteroaryl of from 5 to 24 carbon atoms as necessary to complete a fused heteroaromatic ring of furyl, thienyl, pyridyl, quinolinyl or other heterocyclic systems;
Group 5: alkoxylamino, alkylamino, or arylamino of from 1 to 24 carbon atoms.

Illustrative examples include 9,10-di-(2-naphthyl)anthracene and 2-t-butyl-9, 10-di-(2-naphthyl)anthracene. Other anthracene derivatives can be useful as a host in the LEL, including derivatives of 9,10-bis[4-(2,2-diphenylethenyl)phenyl]anthracene.

The monoanthracene derivative of Formula (IV) is also a useful host material capable of supporting electroluminescence, and are particularly suitable for light emission of wavelengths longer than 400 nm, e.g., blue, green, yellow, orange or red. Anthracene derivatives of Formula (IV) are described in commonly assigned U.S. patent application Ser. No. 10/693,121 filed Oct. 24, 2003 by Lelia Cosimbescu et al., entitled “Electroluminescent Device With Anthracene Derivative Host”, the disclosure of which is herein incorporated by reference, 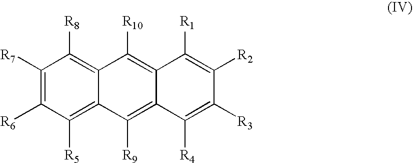
wherein:

R₁-R₈ are H; and

R₉ is a naphthyl group containing no fused rings with aliphatic carbon ring members; provided that R₉ and R₁₀ are not the same, and are free of amines and sulfur compounds. Suitably, R₉ is a substituted naphthyl group with one or more further fused rings such that it forms a fused aromatic ring system, including a phenanthryl, pyrenyl, fluoranthene, perylene, or substituted with one or more substituents including fluorine, cyano group, hydroxy, alkyl, alkoxy, aryloxy, aryl, a heterocyclic oxy group, carboxy, trimethylsilyl group, or an unsubstituted naphthyl group of two fused rings. Conveniently, R₉ is 2-naphthyl, or 1-naphthyl substituted or unsubstituted in the para position; and

R¹⁰ is a biphenyl group having no fused rings with aliphatic carbon ring members. Suitably R¹⁰ is a substituted biphenyl group, such that is forms a fused aromatic ring system including but not limited to a naphthyl, phenanthryl, perylene, or substituted with one or more substituents including fluorine, cyano group, hydroxy, alkyl, alkoxy, aryloxy, aryl, a heterocyclic oxy group, carboxy, trimethylsilyl group, or an unsubstituted biphenyl group. Conveniently, R₁₀ is 4-biphenyl, 3-biphenyl unsubstituted or substituted with another phenyl ring without fused rings to form a terphenyl ring system, or 2-biphenyl. Particularly useful is 9-(2-naphthyl)-10-(4-biphenyl)anthracene.

Another useful class of anthracene derivatives is represented by general formula (V)
A1—L—A2 (V)
wherein A 1 and A 2 each represent a substituted or unsubstituted monophenyl-anthryl group or a substituted or unsubstituted diphenylanthryl group and can be the same as or different from each other and L represents a single bond or a divalent linking group.

Another useful class of anthracene derivatives is represented by general formula (VI)
A3—An—A4 (VI)
wherein An represents a substituted or unsubstituted divalent anthracene group, A3 and A4 each represent a substituted or unsubstituted monovalent condensed aromatic ring group or a substituted or unsubstituted non-condensed ring aryl group having 6 or more carbon atoms and can be the same with or different from each other.

Asymmetric anthracene derivatives as disclosed in U.S. Pat. No. 6,465,115 and WO 2004/018587 are useful hosts and these compounds are represented by general formulas (VII) and (VIII) shown below, alone or as a component in a mixture 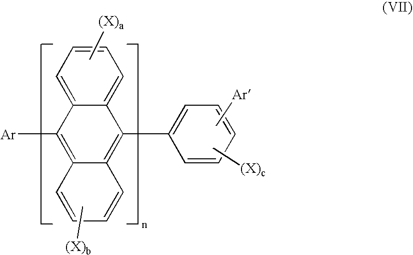
wherein:
Ar is an (un)substituted condensed aromatic group of 10-50 nuclear carbon atoms;
Ar¹ is an (un)substituted aromatic group of 6-50 nuclear carbon atoms;
X is an (un)substituted aromatic group of 6-50 nuclear carbon atoms, (un)substituted aromatic heterocyclic group of 5-50 nuclear carbon atoms, (un)substituted alkyl group of 1-50 carbon atoms, (un)substituted alkoxy group of 1-50 carbon atoms, (un)substituted arylalkyl group of 6-50 carbon atoms, (un)substituted aryloxy group of 5-50 nuclear carbon atoms, (un)substituted arylthio group of 5-50 nuclear carbon atoms, (un)substituted alkoxycarbonyl group of 1-50 carbon atoms, carboxy group, halogen atom, cyano group, nitro group, or hydroxy group;
a, b, and c are whole numbers of 0-4; and n is a whole number of 1-3;
and when n is 2 or more, the formula inside the parenthesis shown below can be the same or different.

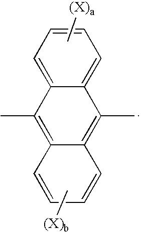

Furthermore, the present invention provides anthracene derivatives represented by general formula (VIII) shown below 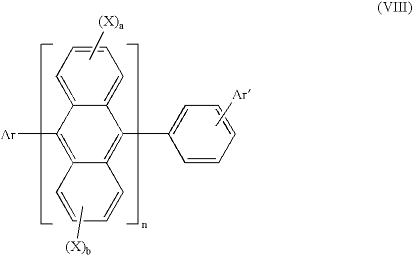
wherein:
Ar is an (un)substituted condensed aromatic group of 10-50 nuclear carbon atoms;
Ar¹ is an (un)substituted aromatic group of 6-50 nuclear carbon atoms;
X is an (un)substituted aromatic group of 6-50 nuclear carbon atoms, (un)substituted aromatic heterocyclic group of 5-50 nuclear carbon atoms, (un)substituted alkyl group of 1-50 carbon atoms, (un)substituted alkoxy group of 1-50 carbon atoms, (un)substituted arylalkyl group of 6-50 carbon atoms, (un)substituted aryloxy group of 5-50 nuclear carbon atoms, (un)substituted arylthio group of 5-50 nuclear carbon atoms, (un)substituted alkoxycarbonyl group of 1-50 carbon atoms, carboxy group, halogen atom, cyano group, nitro group, or hydroxy group;

a, b, and c are whole numbers of 0-4; and n is a whole number of 1-3; and

when n is 2 or more, the formula inside the parenthesis shown below can be the same or different 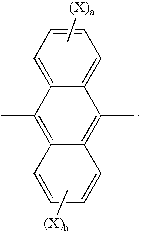
Specific examples of useful anthracene materials for use in a light-emitting layer include 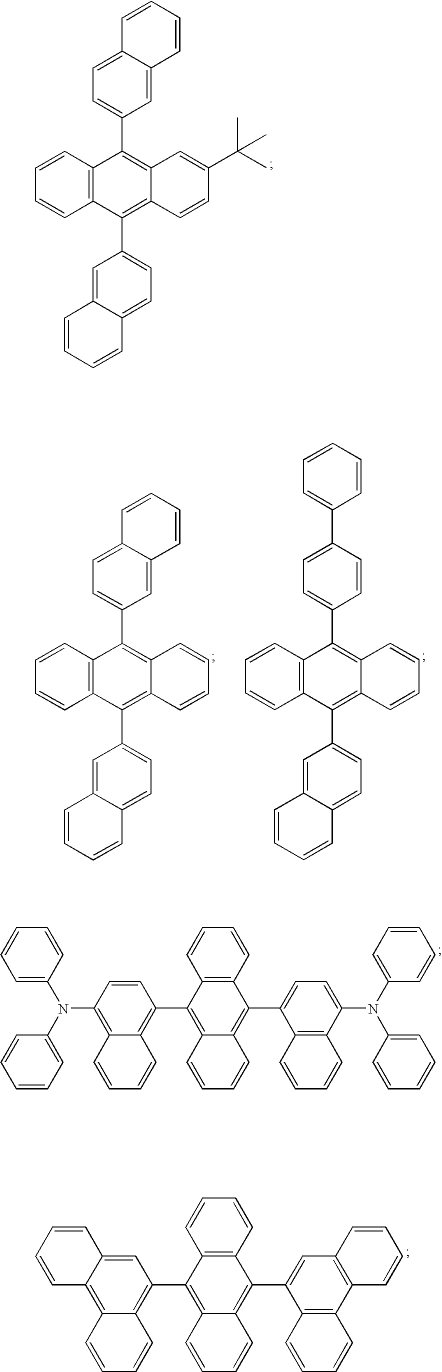 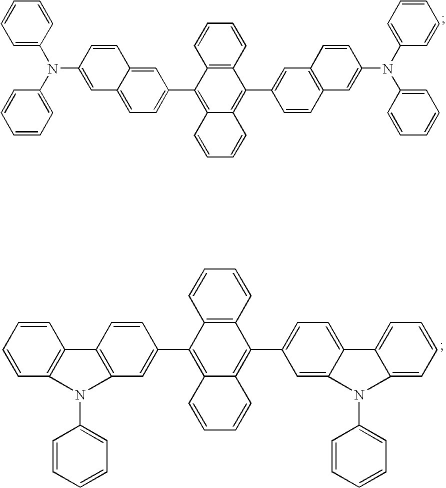 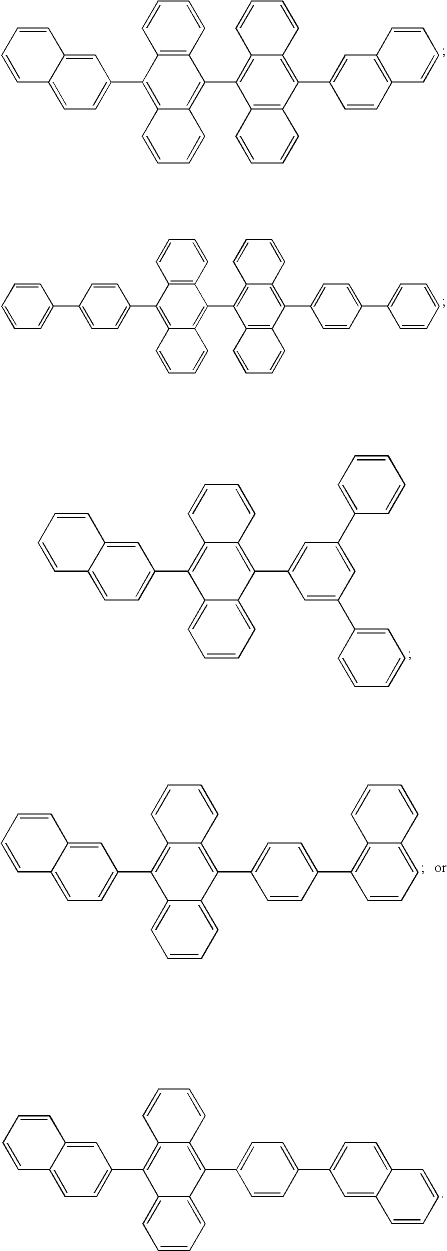
Benzazole derivatives (Formula G) constitute another class of useful host materials capable of supporting electroluminescence, and are particularly suitable for light emission of wavelengths longer than 400 nm, e.g., blue, green, yellow, orange or red. 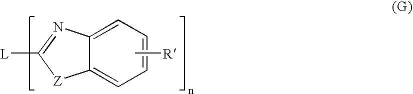
wherein:
n is an integer of 3 to 8;
Z is O, NR or S; and
R and R′ are individually hydrogen; alkyl of from 1 to 24 carbon atoms, for example, propyl, t-butyl, heptyl, and the like; aryl or hetero-atom substituted aryl of from 5 to 20 carbon atoms for example phenyl and naphthyl, furyl, thienyl, pyridyl, quinolinyl and other heterocyclic systems; or halo such as chloro, fluoro; or atoms necessary to complete a fused aromatic ring; and
L is a linkage unit consisting of alkyl, aryl, substituted alkyl, or substituted aryl, which connects the multiple benzazoles together. L may be either conjugated with the multiple benzazoles or not in conjugation with them. An example of a useful benzazole is 2,2′,2″-(1,3,5-phenylene)tris[1-phenyl- 1 H-benzimidazole].

Styrylarylene derivatives as described in U.S. Pat. No. 5,121,029 and JP 08333569 are also useful hosts for blue emission. For example, 9,10-bis[4-(2,2-diphenylethenyl)phenyl]anthracene and 4,4′-bis(2,2-diphenylethenyl)-1,1′-biphenyl (DPVBi) are useful hosts for blue emission.

Useful fluorescent emitting materials include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrylium and thiapyrylium compounds, fluorene derivatives, periflanthene derivatives, indenoperylene derivatives, bis(azinyl)imine boron compounds, bis(azinyl)methene compounds, and carbostyryl compounds.

Illustrative examples of useful materials include, but are not limited to, the following:

| | |
|---|---|
| 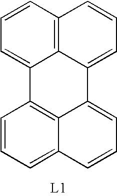 | 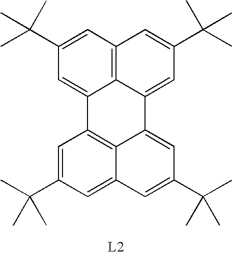 |
| 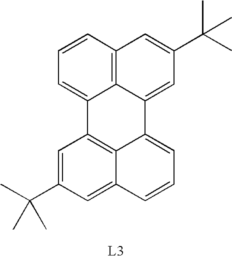 | 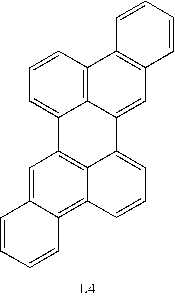 |
| 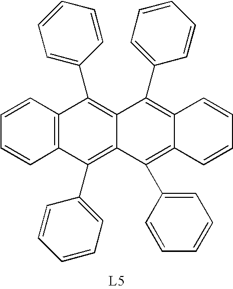 | 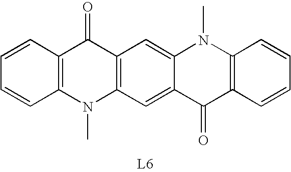 |
| 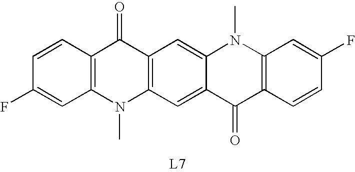 | 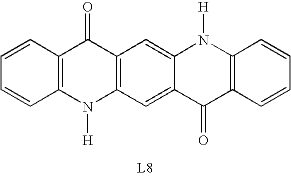 |
| 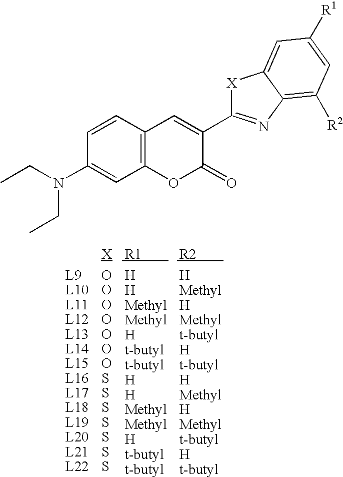 | 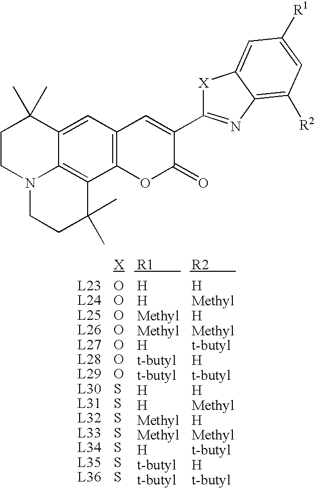 |
| 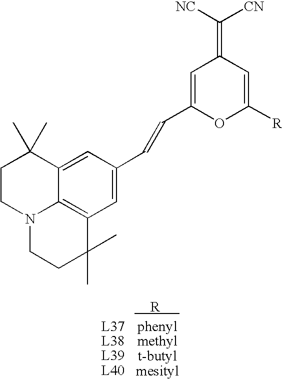 | 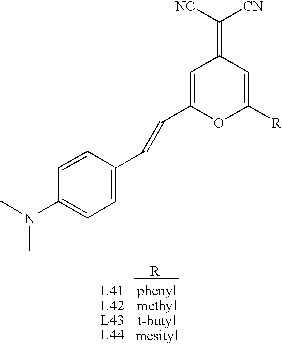 |
| 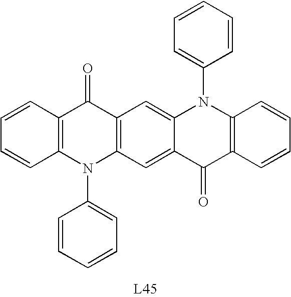 | 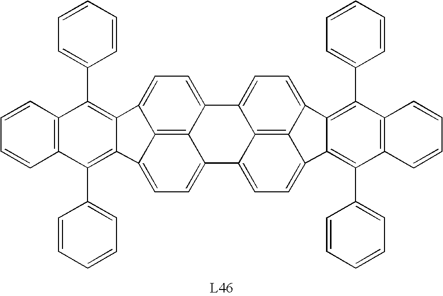 |
| 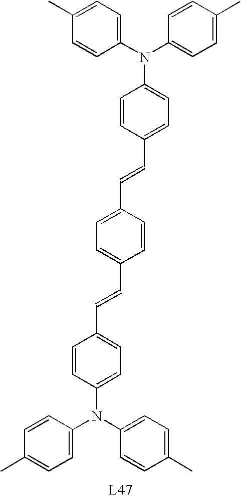 | 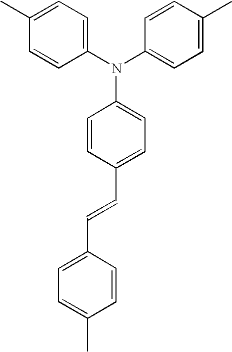 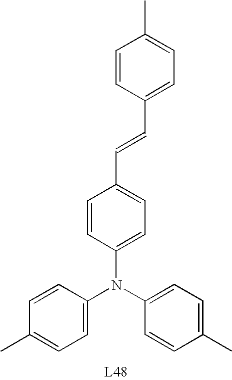 |
| 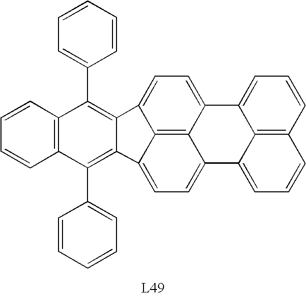 | 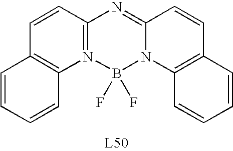 |
| 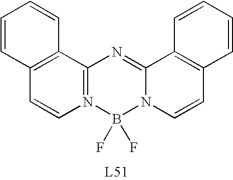 | 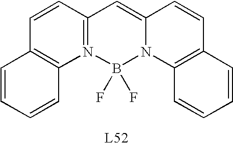 |
| 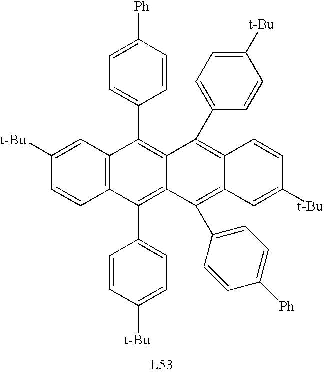 | 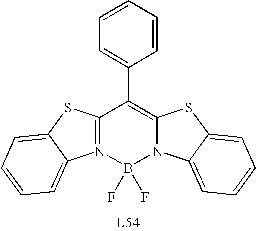 |
| 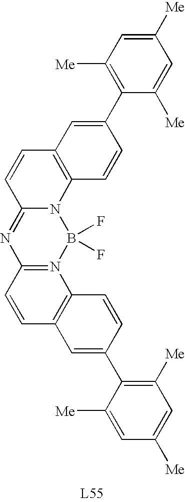 | |

Light-emitting phosphorescent materials may be used in the EL device. For convenience, the phosphorescent complex guest material may be referred to herein as a phosphorescent material. The phosphorescent material typically includes one or more ligands, for example monoanionic ligands that can be coordinated to a metal through an sp² carbon and a heteroatom. Conveniently, the ligand can be phenylpyridine (ppy) or derivatives or analogs thereof. Examples of some useful phosphorescent organometallic materials include tris(2-phenylpyridinato-N,C^{2′}) iridium(III), bis(2-phenylpyridinato-N,C²) iridium(III)(acetylacetonate), and bis(2-phenylpyridinato-N,C^{2′})platinum(II). Usefully, many phosphorescent organometallic materials emit in the green region of the spectrum, that is, with a maximum emission in the range of 510 to 570 nm.

Phosphorescent materials may be used singly or in combinations with other phosphorescent materials, either in the same or different layers. Phosphorescent materials and suitable hosts are described in WO 00/57676, WO 00/70655, WO 01/41512 A1, WO 02/15645 A1, US 2003/0017361 A1, WO 01/93642 A1, WO 01/39234 A2, U.S. Pat. No. 6,458,475 B1, WO 02/071813 A1, US 6,573,651 B2, US 2002/0197511 A1, WO 02/074015 A2, U.S. Pat. No. 6,451,455 B1, US 2003/0072964 A1, US 2003/0068528 A1, U.S. Pat. No. 6,413,656 B1, U.S. Pat. No. 6,515,298 B2, U.S. Pat. No. 6,451,415 BI, U.S. Pat. No. 6,097,147, US 2003/0124381 A1, US 2003/0059646 A1, US 2003/0054198 A1, EP 1 239 526 A2, EP 1 238 981 A2, EP 1 244 155 A2, US 2002/0100906 A1, US 2003/0068526 A1, US 2003/0068535 A1, JP 2003073387A, JP 2003 073388A, US 2003/0141809 A1, US 2003/0040627 A1, JP 2003059667A, JP 2003073665A, and US 2002/0121638 A1.

The emission wavelengths of cyclometallated Ir(III) complexes of the type IrL₃ and IrL₂L′, such as the green-emitting fac-tris(2-phenylpyridinato-N,C^{2′}) iridium(III) and bis(2-phenylpyridinato-N,C^{2′})iridium(III)(acetylacetonate) may be shifted by substitution of electron donating or withdrawing groups at appropriate positions on the cyclometallating ligand L, or by choice of different heterocycles for the cyclometallating ligand L. The emission wavelengths may also be shifted by choice of the ancillary ligand L′. Examples of red emitters are the bis(2-(2′-benzothienyl)pyridinato-N,C^{3′})iridium(III)(acetylacetonate) and tris(2-phenylisoquinolinato-N,C)iridium(III). A blue-emitting example is bis(2-(4,6-difluorophenyl)-pyridinato-N,C^{2′})iridium(III) (picolinate).

Red electrophosphorescence has been reported, using bis(2-(2′-benzo[4,5-a]thienyl)pyridinato-N, C³) iridium (acetylacetonate) [Btp₂Ir(acac)]as the phosphorescent material (C. Adachi, S. Lamansky, M. A. Baldo, R. C. Kwong, M. E. Thompson, and S. R. Forrest, App. Phys. Lett., 78, 1622-1624 (2001)).

Other important phosphorescent materials include cyclometallated Pt(II) complexes such as cis-bis(2-phenylpyridinato-N,C^{2′})platinum(II), cis-bis(2-(2′-thienyl)pyridinato-N,C³′) platinum(II), cis-bis(2-(2′-thienyl)quinolinato-N,C⁵′) platinum(II), or (2-(4,6-difluorophenyl)pyridinato-N,C^{2′}) platinum (II) (acetylacetonate). Pt (II) porphyrin complexes such as 2,3,7,8,12,13,17,18-octaethyl-21H, 23H-porphine platinum(II) are also usefuil phosphorescent materials.

Still other examples of useful phosphorescent materials include coordination complexes of the trivalent lanthanides such as Tb³⁺ and Eu³⁺ (J. Kido et al., Appl. Phys. Lett., 65, 2124 (1994)).

Suitable host materials for phosphorescent materials should be selected so that transfer of a triplet exciton can occur efficiently from the host material to the phosphorescent material but cannot occur efficiently from the phosphorescent material to the host material. Therefore, it is highly desirable that the triplet energy of the phosphorescent material be lower than the triplet energy of the host. Generally speaking, a large triplet energy implies a large optical bandgap. However, the band gap of the host should not be chosen so large as to cause an unacceptable barrier to injection of charge carriers into the light-emitting layer and an unacceptable increase in the drive voltage of the OLED. Suitable host materials are described in WO 00/70655 A2; 01/39234 A2; 01/93642 A1; 02/074015 A2; 02/15645 A1, and US 20020117662. Suitable hosts include certain aryl amines, triazoles, indoles and carbazole compounds. Examples of desirable hosts are 4,4′-N,N′-dicarbazole-biphenyl, otherwise known as 4,4′-bis(carbazol-9-yl)biphenyl or CBP; 4,4′-N,N′-dicarbazole-2,2′-dimethyl-biphenyl, otherwise known as 2,2′-dimethyl-4,4′-bis(carbazol-9-yl)biphenyl or CDBP; 1,3-bis(N,N′-dicarbazole)benzene, otherwise known as 1,3-bis(carbazol-9-yl)benzene, and poly(N-vinylcarbazole), including their derivatives.

Desirable hosts comprising a mixture of materials are described in commonly assigned U.S. Ser. No. 10/945,337 filed Sep. 20, 2004, and U.S. Ser. No. 11/015,929 filed Dec. 17, 2004 that describe an EL device in which the light emitting layer includes a hole transporting compound, certain aluminum chelate materials, and a light-emitting phosphorescent compound.

Desirable host materials are capable of forming a continuous film.

Hole-Blocking Layer (HBL)

In addition to suitable hosts, an OLED device employing a phosphorescent material often requires at least one hole-blocking layer placed between the electron-transporting layer 111 and the light-emitting layer 109 to help confine the excitons and recombination events to the light-emitting layer comprising the host and phosphorescent material. In this case, there should be an energy barrier for hole migration from the host into the hole-blocking layer, while electrons should pass readily from the hole-blocking layer into the light-emitting layer comprising a host and a phosphorescent material. The first requirement entails that the ionization potential of the hole-blocking layer be larger than that of the light-emitting layer 109, desirably by 0.2 eV or more. The second requirement entails that the electron affinity of the hole-blocking layer not greatly exceed that of the light-emitting layer 109, and desirably be either less than that of light-emitting layer or not exceed that of the light-emitting layer by more than about 0.2 eV.

When used with an electron-transporting layer whose characteristic luminescence is green, such as an Alq-containing electron-transporting layer as described below, the requirements concerning the energies of the highest occupied molecular orbital (HOMO) and lowest unoccupied molecular orbital (LUMO) of the material of the hole-blocking layer frequently result in a characteristic luminescence of the hole-blocking layer at shorter wavelengths than that of the electron-transporting layer, such as blue, violet, or ultraviolet luminescence. Thus, it is desirable that the characteristic luminescence of the material of a hole-blocking layer be blue, violet, or ultraviolet. It is further desirable, but not absolutely required, that the triplet energy of the hole-blocking material be greater than that of the phosphorescent material. Suitable hole-blocking materials are described in WO 00/70655A2 and WO 01/93642 A1. Two examples of useful hole-blocking materials are bathocuproine (BCP) and bis(2-methyl-8-quinolinolato) (4-phenylphenolato)aluminum(III) (BAlq). The characteristic luminescence of BCP is in the ultraviolet, and that of BAlq is blue. Metal complexes other than BAlq are also known to block holes and excitons as described in US 20030068528. In addition, US 20030175553 A1 describes the use of fac-tris(I -phenylpyrazolato-N,C^{2′})iridium(III) (Irppz) for this purpose.

When a hole-blocking layer is used, its thickness can be between 2 and 100 nm and suitably between 5 and 10 nm.

Electron-Transiorting Layer (ETL)

Desirable thin film-forming materials for use in forming the electron-transporting layer 111 of the organic EL devices of this invention are metal-chelated oxinoid compounds, including chelates of oxine itself (also commonly referred to as 8-quinolinol or 8-hydroxyquinoline). Such compounds help to inject and transport electrons, exhibit high levels of performance, and are readily fabricated in the form of thin films. Exemplary of contemplated oxinoid compounds are those satisfying structural formula (E), previously described.

Other electron-transporting materials suitable for use in the electron-transporting layer 111 include various butadiene derivatives as disclosed in U.S. Pat. No. 4,356,429 and various heterocyclic optical brighteners as described in U.S. Pat. No. 4,539,507. Benzazoles satisfying structural formula (G) are also useful electron transporting materials. Triazines are also known to be useful as electron transporting materials. Further useful materials are silacyclopentadiene derivatives described in EP 1,480,280; EP 1,478,032; and EP 1,469,533. Substituted 1,10-phenanthroline compounds such as 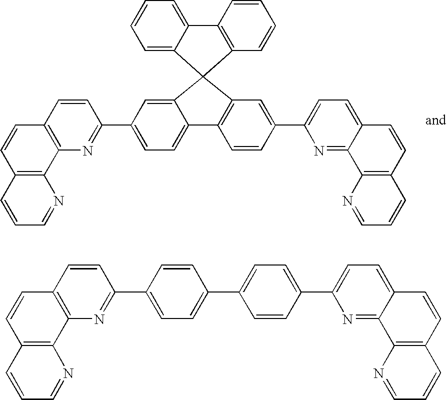
are disclosed in JP2003-115387; JP2004-311184; JP2001-267080; and WO2002-043449. Pyridine derivatives are described in JP2004-200162 as useful electron transporting materials.

If both a hole-blocking layer and an electron-transporting layer 111 are used, electrons should pass readily from the electron-transporting layer 111 into the hole-blocking layer. Therefore, the electron affinity of the electron-transporting layer 111 should not greatly exceed that of the hole-blocking layer. Desirably, the electron affinity of the electron-transporting layer should be less than that of the hole-blocking layer or not exceed it by more than about 0.2 eV.

If an electron-transporting layer is used, its thickness may be between 2 and 100 nm and suitably between 5 and 20 nm.

Electron-Iniecting Layer (EIL)

Electron- injecting layers, when present, include those described in U.S. Pat. Nos. 5,608,287; 5,776,622; 5,776,623; 6,137,223; and 6,140,763, U.S. Pat. No. 6,914,269 the disclosures of which are incorporated herein by reference. An electron-injecting layer generally consists of a material having a work function less than 4.0 eV. A thin-film containing low work-function alkaline metals or alkaline earth metals, such as Li, Cs, Ca, Mg can be employed. In addition, an organic material doped with these low work-function metals can also be used effectively as the electron-injecting layer. Examples are Li- or Cs-doped Alq. In one suitable embodiment the electron-injecting layer includes LiF. In practice, the electron-injecting layer is often a thin layer deposited to a suitable thickness in a range of 0.1-3.0 nm.

Other Common Organic Layers and Device Architectures

In some instances, layers 109 and 111 can optionally be collapsed into a single layer that serves the function of supporting both light emission and electron transportation. It is also known in the art that emitting dopants may be added to the hole-transporting layer, which may serve as a host. Multiple dopants may be added to one or more layers in order to create a white-emitting OLED, for example, by combining blue- and yellow-emitting materials, cyan- and red-emitting materials, or red-, green-, and blue-emitting materials. White-emitting devices are described, for example, in EP 1 187 235, EP 1 182 244, U.S. Pat. No. 5,683,823, U.S. Pat. No. 5,503,910, U.S. Pat. No. 5,405,709, and U.S. Pat. No. 5,283,182, US 20020186214, US 20020025419, US 20040009367, and U.S. Pat. No. 6627333.

Additional layers such as exciton, electron and hole-blocking layers as taught in the art may be employed in devices of this invention. Hole-blocking layers are commonly used to improve efficiency of phosphorescent emitter devices, for example, as in US 20020015859, WO 00/70655A2, WO 01/93642A1, US 20030068528 and US 20030175553 A1.

This invention may be used in so-called stacked device architecture, for example, as taught in U.S. Pat. No. 5,703,436 and U.S. Pat. No. 6,337,492.

Deposition of Organic Layers

The organic materials mentioned above are suitably deposited through a vapor-phase method such as sublimation, but can be deposited from a fluid, for example, from a solvent with an optional binder to improve film formation. If the material is a polymer, solvent deposition is useful but other methods can be used, such as sputtering or thermal transfer from a donor sheet. The material to be deposited by sublimation can be vaporized from a sublimation “boat” often comprised of a tantalum material, e.g., as described in U.S. Pat. No. 6,237,529, or can be first coated onto a donor sheet and then sublimed in closer proximity to the substrate. Layers with a mixture of materials can utilize separate sublimation boats or the materials can be pre-mixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. Nos. 5,688,551, 5,851,709 and 6,066,357) and inkjet method (U.S. Pat. No. 6,066,357).

One preferred method for depositing the materials of the present invention is described in US 2004/0255857 and U.S. Ser. No. 10/945,941 where different source evaporators are used to evaporate each of the materials of the present invention. A second preferred method involves the use of flash evaporation where materials are metered along a material feed path in which the material feed path is temperature controlled. Such a preferred method is described in the following co-assigned patent applications: U.S. Ser. No. 10/784,585; U.S. Ser. No. 10/805,980; USSN 10/945,940; U.S. Ser. No. 10/945,941; U.S. Ser. No. 11/050,924; and U.S. Ser. No. 11/050,934. Using this second method, each material may be evaporated using different source evaporators or the solid materials may be mixed prior to evaporation using the same source evaporator.

Encapsulation

Most OLED devices are sensitive to moisture or oxygen, or both, so they are commonly sealed in an inert atmosphere such as nitrogen or argon. In sealing an OLED device in an inert environment, a protective cover can be attached using an organic adhesive, a metal solder, or a low melting temperature glass. Commonly, a getter or desiccant is also provided within the sealed space. Useful getters and desiccants include, alkali and alkaline metals, alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as SiOx, Teflon, and alternating inorganic/polymeric layers are known in the art for encapsulation.

Optical Optimization

OLED devices of this invention can employ various well-known optical effects in order to enhance its properties if desired. This includes optimizing layer thicknesses to yield maximum light transmission, providing dielectric mirror structures, replacing reflective electrodes with light-absorbing electrodes, providing anti glare or anti-reflection coatings over the display, providing a polarizing medium over the display, or providing colored, neutral density, or color conversion filters in functional relationship with the light emitting areas of the display. Filters, polarizers, and anti-glare or anti-reflection coatings can also be provided over a cover or as part of a cover.

The OLED device may have a microcavity structure. In one useful example, one of the metallic electrodes is essentially opaque and reflective; the other one is reflective and semitransparent. The reflective electrode is preferably selected from Au, Ag, Mg, Ca, or alloys thereof. Because of the presence of the two reflecting metal electrodes, the device has a microcavity structure. The strong optical interference in this structure results in a resonance condition. Emission near the resonance wavelength is enhanced and emission away from the resonance wavelength is depressed. The optical path length can be tuned by selecting the thickness of the organic layers or by placing a transparent optical spacer between the electrodes. For example, an OLED device of this invention can have ITO spacer layer placed between a reflective anode and the organic EL media, with a semitransparent cathode over the organic EL media.

Embodiments of the invention may provide advantageous features such as higher luminous yield, lower drive voltage, and higher power efficiency, longer operating lifetimes or ease of manufacture. Embodiments of devices useful in the invention can provide a wide range of hues including those useful in the emission of white light (directly or through filters to provide multicolor displays). Embodiments of the invention can also provide an area lighting device.

The invention and its advantages are further illustrated by the specific examples that follow. Unless otherwise specified, the term “percentage” or “percent” and the symbol “%” of a material indicate the volume percent of the material in the layer in which it is present.

### EXAMPLE 1

### Synthesis of Inv-1, N,N,N′,N′, 9,10-hexaphenyl-2,6-anthracenediamine.

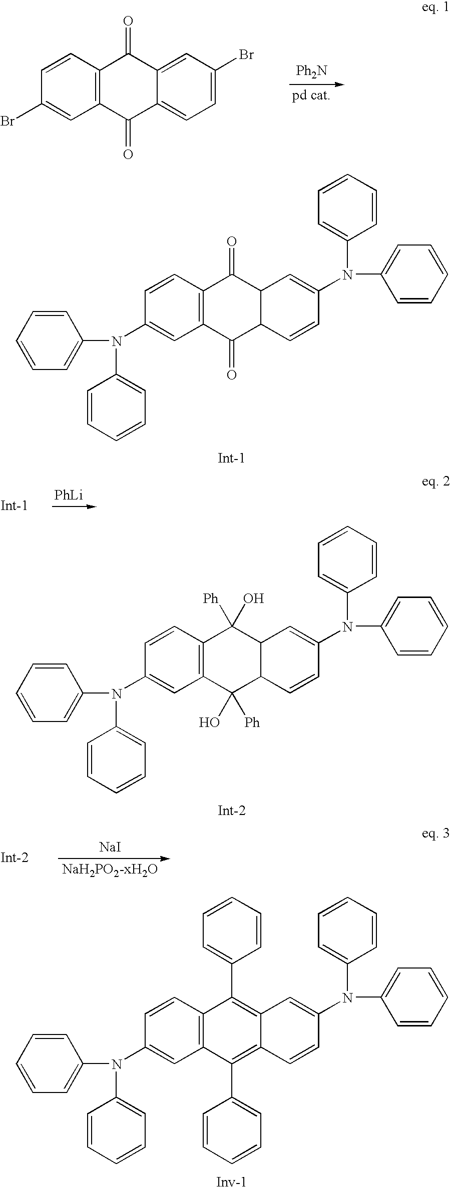

10 Inv-1, N,N,N′,N′, 9,10-hexaphenyl-2,6-anthracenediamine, was prepared according to equation 1- equation 3. Under a nitrogen atmosphere 2,6-dibromoanthraquinone (44 g, 0.12 mol), diphenylamine (42.5 g, 0.26 mol), sodium tert-butoxide (27 g, 0.27 mol), palladium(II) acetate (1.5 g, 0.007 mol), and 400 ml of toluene were added together. With stirring, tri-tert-butylphosphine (1.1 g, 0.005 mol) was added and the reaction was heated at 90 ° C. for 12 hours. Upon cooling, the reaction mixture was passed through a pad of silica gel, eluting with CH₂Cl₂. Solvents were removed and the crude solid was further purified by chromatography to yield 48.9 g (75% yield) of N,N,N′,N′-tetraphenyl-2,6-diamino-9,10-anthracenedione (Int-1, eq. 1) as a red solid. FD-MS (m/z): 542 Compound (Int-1) (20 g, 0.036 moles) and 200 ml anhydrous tetrahydrofuran (THF) were placed under nitrogen and cooled to −78° C. with stirring. Phenyllithium (1.8 M in cyclohexane:ether [70:30], 45 ml, 0.081 mol) was added drop-wise and the reaction mixture was allowed to warm to room temperature overnight. The reaction mixture was then poured into water and 200 ml CH₂Cl₂ was added. The organic layer was separated from water layer, and the organic layer was then washed with water, dried over Na₂SO₄, and concentrated to yield crude N,N,N′,N′,9,10-hexaphenyl-2,6-diamino-9,10-dihydro-9,10-anthracenediol (Int-2).

Crude Int-2 was dissolved in 500 ml acetic acid. Sodium iodide (50 g), and sodium hypophosphite hydrate (50 g) were added with stirring. The mixture was heated to reflux for 60 minutes, cooled to room temperature and poured into water. The precipitated solid was collected by filtration, washed with water, washed with a small amount of methanol (−20 ml) and then dried. Purification by column chromatography yielded 14.0 g (57% yield) of pure N,N,N′,N′,9,10-hexaphenyl-2,6-anthracenediamine (Inv-1) as an orange solid. This material was sublimed at a pressure of 600 mTorr and a temperature of 265° C. using train sublimation. FD-MS (m/z): 664.

### EXAMPLE 2

### Synthesis of N,N,N′,N′-tetrakis(4-methylphenyl)-9,10-diphenyl-2,6-anthracenediamine (Inv-3).

Under a nitrogen atmosphere 2,6-dibromoanthraquinone (5 g, 13.7 mmol), di-tolylamine (5.6 g, 28.4 mmol), sodium tert-butoxide (3.1 g, 32.2 mmol), palladium(II) acetate (0.17 g, 0.75 mmol), and 50 ml of toluene were added together. With stirring, tri-tert-butylphosphine (0.13 g, 0.64 mmol) was added and the reaction was heated at 90 ° C. for 12 hours. Upon cooling, the reaction mixture was passed through pad of silica gel, eluting with CH₂Cl₂. Solvents were removed and the crude solid was further purified by chromatography to yield 5.0 g (61% yield) of N,N,N′,N′-tetrakis(4-methylphenyl)-2,6-diamino-9,10-anthracenedione as a red solid. FD-MS (m/z): 598

N,N,N′,N′-tetrakis(4-methylphenyl)-2,6-diamino-9,10-anthracenedione (2.5 g, 41.8 mmol) and 50 ml anhydrous THF were placed under nitrogen and cooled to -78° C. with stirring. Phenyllithium (1.8 M in cyclohexane:ether [70:30], 6.0 ml, 10.8 mmol) was added drop-wise and the reaction was allowed to warm to room temperature overnight. The reaction mixture was poured into water and 50 ml CH₂Cl₂ was added. Organic layer separated from the water layer, and the organic layer was then washed with water, dried over Na₂SO₄, and concentrated to yield crude N,N,N′,N′-tetrakis(4-methylphenyl)-2,6-diamino-9,10-dihydro-9,10-diphenyl-9,10-anthracenediol.

The crude N,N,N′,N′-tetrakis(4-methylphenyl)-2,6-diamino-9,10-dihydro-9,10-diphenyl-9,10-anthracenediol was dissolved in 65 ml acetic acid. Sodium iodide (10 g), and sodium hypophosphite hydrate (10 g) were added with stirring. The mixture was heated to reflux for 60 minutes, cooled to room temperature and poured into water. The precipitated solid was collected by filtration, washed with water, washed with a small amount of methanol (−5 ml) and then dried. Purification by column chromatography yielded 2.3 g (76% yield) of pure N,N,N′,N′-tetrakis(4-methylphenyl)-9,10-diphenyl-2,6-anthracenediamine (Inv-3) as an orange solid. At a pressure of 600 mTorr, Inv-3 sublimed at 290 ° C. using train sublimation. FD-MS (m/z): 720. Example 3. The synthesis of N,N′-di-2-naphthalenyl-N,N′,9,10-tetraphenyl-2,6-anthracenediamine (Inv-4).

Under a nitrogen atmosphere, 2,6-dibromoanthraquinone (11.0 g, 30.1 mmol), N-phenyl-2-naphthalenamine (15.0 g, 68.5 mmol), sodium tert-butoxide (6.75 g, 70.2 mmol), palladium(II) acetate (0.38 g, 1.7 mmol), and 100 ml of toluene were added together. With stirring, tri-tert-butylphosphine (0.28 g, 1.4 mmol) was added and the reaction was heated at 90 ° C. for 12 hours. Upon cooling, the reaction mixture was passed through a pad of silica gel, and eluted with CH₂Cl₂. Solvents were removed and the crude solid further purified by chromatography to yield 17.3 g (89.7% yield ) of N,N,N′,N′-tetrakis(4-methylphenyl)-2,6-diamino-9,10-anthracenedione as a red solid. FD-MS (m/z): 642

N,N,N′,N′-tetrakis(4-methylphenyl)-2,6-diamino-9,10-anthracenedione (2.5 g, 3.1 mmol) and 50 ml anhydrous THF were placed under nitrogen and cooled to −78° C. with stirring. Phenyllithium (1.8 M in cyclohexane:ether [70:30], 5.0 ml, 9 mmol) was added drop-wise and the reaction was allowed to warm to room temperature overnight. The reaction mixture was poured into water and 50 ml CH₂Cl₂ was added. The organic layer was separated from the water layer, and the organic layer was then washed with water, dried over Na₂SO₄, and concentrated to yield crude N,N′-di-2-naphthalenyl-N,N′,9,10-tetraphenyl-2,6-diamino-9,10-dihydro-9,10-anthracenediol.

The crude diol was dissolved in 65 ml of acetic acid. Sodium iodide (10 g), and sodium hypophosphite hydrate (10 g) were added with stirring. The mixture was heated to reflux for 60 minutes, cooled to room temperature and poured to water. The precipitated solid was collected by filtration, washed with a water and then a small amount of methanol (p10 ml) and dried. Purification by column chromatography yielded 0.5 g (17% yield) of pure N,N′-di-2-naphthalenyl-N,N′,9,10-tetraphenyl-2,6-anthracenediamine (Inv-4) as an orange solid. At a pressure of 600 mTorr, Inv-4 sublimed at 300° C. using train sublimation. FD-MS (m/z): 764.

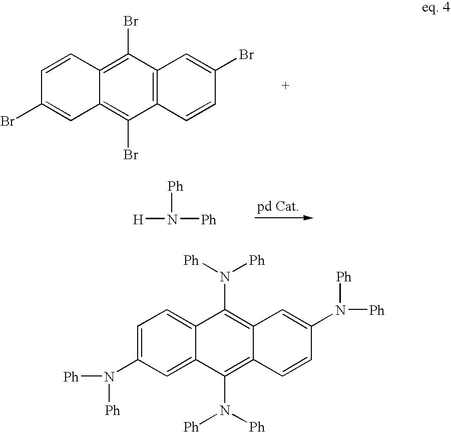

### EXAMPLE 4

### Synthesis of N,N,N′,N′,N″,N″,N′″,N′″-octaphenyl-2,6,9,10-tetraaminoanthracene (Inv-23).

Inv-23 was prepared according to equation 4. Under a nitrogen atmosphere 2,6,9,10-tetrabromoanthracene (1.5 g, 3.0 mmol), diphenylamine (2.57 g, 15.2 mmol), sodium tert-butoxide (1.63 g, 16.3 mrnol), palladium(II) acetate (90 mg, 0.4 mmol), and 25 ml of toluene were added together. With stirring, tri-tert-butylphosphine (67 mg, 0.3 mmol) was added and the reaction was heated at 90° C. for 12 hours. Upon cooling, the reaction mixture was passed through a pad of silica gel, eluting with CH₂Cl₂. Solvents were removed and the crude solid was further purified by chromatography to yield 1.1 g (43% yield) of N,N,N′,N′,N″,N″,N′″,N′″-octaphenyl-2,6,9,10-tetraaminoanthracene (Inv-23) as a red solid. FD-MS (m/z): 846

### EXAMPLE 5

### Measurement of oxidation potentials.

A Model CH1660 electrochemical analyzer (CH Instruments, Inc., Austin, Tex.) was employed to carry out the electrochemical measurements. Cyclic voltammetry (CV) and Osteryoung square-wave voltammetry (SWV) were used to characterize the redox properties of the compounds of interest. A glassy carbon (GC) disk electrode (A=0.07lcm ) was used as working electrode. The GC electrode was polished with 0.05 um alumina slurry, followed by sonication cleaning in Milli-Q deionized water twice and rinsed with acetone in between water cleaning. The electrode was finally cleaned and activated by electrochemical treatment prior to use. A platinum wire served as counter electrode and a saturated calomel electrode (SCE) was used as a quasi-reference electrode to complete a standard 3-electrode electrochemical cell. Ferrocene (Fc) was used as an internal standard (EFC=0.50 vs.SCE in 1:1 acetonitrile/toluene. A mixture of acetonitrile and toluene (MeCN/Toluene, 1/1, v/v) was used as the organic solvent system. The supporting electrolyte, tetrabutylammonium tetraflouroborate (TBAF) was recrystallized twice in isopropanol and dried under vacuum for three days. All solvents used were low water content (<20 ppm water). All compounds were analyzed as received. The testing solution was purged with high purity nitrogen gas for approximately 5 minutes to remove oxygen and a nitrogen blanket was kept on the top of the solution during the course of the experiments. All measurements were performed at ambient temperature of 25±1° C.

Sonication was used to aid the dissolution. The non-dissolved solids were filtered via a 0.45 um Whatman glass microfiber syringeless filter prior to the voltammetric measurements.

The oxidation potentials were determined either by averaging the anodic peak potential (Ep,a) and cathodic peak potential (Ep,c) for reversible or quasi-reversible electrode processes or on the basis of peak potentials (in SWV) for irreversible processes. The oxidation potentials reported refer to the first event electron transfer, i.e. generation of the radical-cation species, which is the process believed to occur in the solid-state. Results are reported in Table 1.

The Eox of C-1 relative to Inv-1 was calculated using the following equation:

ti Eox=−17.5*Ehomo−2.17.

Ehomo is the HOMO energy taken from a B3LYP/MIDI! geometry optimization using the PQS computer code (PQS v3.2, Parallel Quantum Solutions, Fayetteville, Ark.). The calculated oxidation potential of C-1 was found to be 0.1 V less than that of Inv-1 and is estimated to be 0.58 V vs. SCE.

TABLE 1
Oxidation Potentials

| | Oxidation Potential |
|---|---|
| Compound | (vs. SCE, V) |
| NPB¹ | 0.86 |
| m-TDATA² | 0.46 |
| Inv-1 | 0.68 |
| Inv-3 | 0.60 |
| Inv-23 | 0.67 |
| C-1 | 0.58³ |

¹NPB: N,N′-di(1-naphthyl)-N,N′-diphenyl-4,4′-diaminobiphenyl.
²m-TDATA: 4,4′,4″-tris[(3-methylphenyl)phenylamino]triphenylamine.
³Estimated from calculations

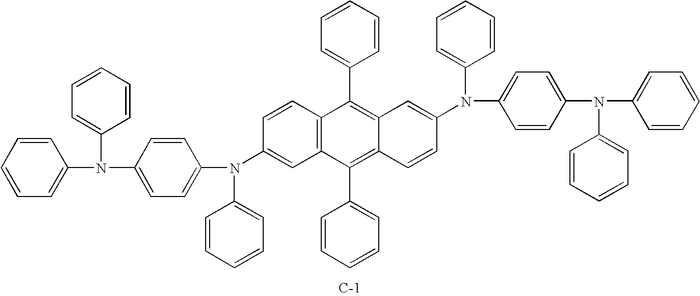

It can be seen from Table 1 that the differences in oxidation potentials between NPB and Inv-1, Inv-3, and Inv-23 are in the range of 0.1-0.3 V.

### EXAMPLE 6

### The Fabrication of Device 1-1, 1-2, and 1-3.

EL device 1-1, satisfying the requirements of the invention, was constructed in the following manner:

A ˜1.1 mm thick glass substrate coated with a transparent ITO conductive layer was cleaned and dried using a commercial glass scrubber tool. The thickness of ITO is about 25 nm and the sheet resistance of the ITO is about 68 Ω/square. The ITO surface was subsequently treated with oxidative plasma to condition the surface as an anode. A layer of CFx, 1 nm thick, was deposited on the clean ITO surface by decomposing CHF₃ gas in an RF plasma treatment chamber. The substrate was then transferred into a vacuum deposition chamber for deposition of all other layers on top of the substrate. The following layers were deposited in the following sequence by sublimation from heated boats under a vacuum of approximately 1 Torr:
a) a 60 nm hole-injecting layer of Inv-1;
b) a 30 nm hole-transporting layer of N,N′-di(l -naphthyl)-N,N′-diphenyl-4,4′-diaminobiphenyl (NPB);
c) a 20 nm light-emitting layer including AIQ₃ (99% by volume) as host and dopant L30 as the light emitting dopant (1% by volume);
d) a 40 nm electron transport layer including AlQ₃ (99% by volume) and Li metal (1% by volume);
e) a 210 nm cathode formed of a 20:1 atomic ratio of Mg and Ag.
   Following that the device was encapsulated in a nitrogen atmosphere along with calcium sulfate as a desiccant.

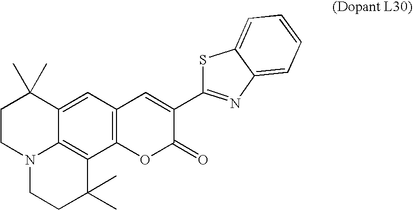

Comparative Device 1-2 was prepared in the same manner as Device 1-1 except that Inv-1 was replaced with m-TDATA (4,4′,4″-tris[(3-methylphenyl)phenylamino]triphenylamine).

A comparative Device 1-3 was prepared as the same manner as Device 1-1, except that layer (a) contained 90 nm of Inv- 1 and layer (b) was omitted.

Devices 1-1, 1-2, and 1-3 were tested for voltage and luminance at a constant current of 20 mA/cm². Device lifetime, which is the time required for the initial luminance to drop by 50%, was measured at room temperature using a DC current of 80 mA/cm² and device performance results are reported in Table 2.

TABLE 2
The performance data for Device 1-1, 1-2, and 1-3.

| | | | Layer Thickness | | | | |
|---|---|---|---|---|---|---|---|
| | Example | | (a) | (b) | Volt. | Lum. | Lifetime |
| Device | Type | Material | (nm) | (nm) | (V) | (cd/m²) | (Hours) |
| 1-1 | Inventive | Inv-1 | 60 | 30 | 6.9 | 2666 | 212 |
| 1-2 | Comparative | mTDATA | 60 | 30 | 9.2 | 3056 | 142 |
| 1-3 | Comparative | Inv-1 | 90 | 0 | 5.8 | 901 | 298 |

It can be seen from Table 2 that inventive Device 1-1 affords the combination of low voltage and high luminance with good stability. Comparative device 1-2 was fabricated with the same components as Device 1-1, except m-TDATA was used in place of Inv-1. Although Device 1-2 does afford higher luminance relative to 1-1, the voltage is 2.3 V higher while the lifetime is 33% shorter than that of Device 1-1.

In comparative Device 1-3, the layer containing Inv-1 is contiguous to the light-emitting layer. The efficiency of comparative Device 1-3 has been drastically reduced by 66% relative to Device 1-1.

It is clear from this data that the compounds of the present invention are superior compared to other compounds in the art. Furthermore, it is also clear that luminance is drastically reduced if a layer containing only compounds of the present invention is placed contiguous to the light-emitting layer. Example 7. Fabrication of Devices 2-1, 2-2, and 2-3.

An EL device, 2-1, satisfying the requirements of the invention was constructed in the following manner.

A -1. 1 mm thick glass substrate coated with a transparent ITO conductive layer was cleaned and dried using a commercial glass scrubber tool. The thickness of ITO is about 25 nm and the sheet resistance of the ITO is about 68 K/square. The ITO surface was subsequently treated with oxidative plasma to condition the surface as an anode. A layer of CFx, 1 nm thick, was deposited on the clean ITO surface by decomposing CHF₃ gas in an RF plasma treatment chamber. The substrate was then transferred into a vacuum deposition chamber for deposition of all other layers on top of the substrate. The following layers were deposited in the following sequence by sublimation from heated boats under a vacuum of approximately 10-6 Torr:
a) a 60 nm hole injecting layer including Inv-1 (97% by volume) and 2,3,5,6-Tetrafluoro-7,7,8,8-tetracyanoquinodimethane [F₄TCNQ](3% by volume);
b) a 30 mn hole-transporting layer including NPB;
c) a 20 nm light-emitting layer including AlQ₃ (99% by volume) as host and dopant L30 as the light emitting dopant (1% by volume);
d) a 40 nm electron transport layer including AIQ₃ (99% by volume) and Li metal (1% by volume);
e) a 210 nm cathode formed of a 20:1 atomic ratio of Mg and Ag. Following that the devices were encapsulated in a nitrogen atmosphere along with calcium sulfate as a desiccant.

Comparative Device, 2-2, was prepared in the same manner as Device 2-1 except that Inv-1 was replaced with m-TDATA.

Comparative Device, 2-3, was prepared in the same manner Device 2-1, except that layer (a) was 90 nm thick and layer (b) was omitted.

Devices 2-1, 2-2, and 2-3 were tested for voltage and luminance at a constant current of 20 m A/cm². Device lifetime, which is the time required for the initial luminance to drop by 50%, was measured at room temperature using a DC current of 80 mA/cm² and all device performance results are reported in Table 3.

TABLE 3
The performance data for Device 2-1, 2-2, and 2-3.

| | | | Layer Thickness | | | | |
|---|---|---|---|---|---|---|---|
| | Example | | (a) | (b) | Volt. | Lum. | Lifetime |
| Device | Type | Material | (nm) | (nm) | (V) | (cd/m²) | (Hours) |
| 2-1 | Inventive | Inv-1 | 60 | 30 | 6.3 | 2318 | 259 |
| 2-2 | Comparative | mTDATA | 60 | 30 | 8.4 | 3170 | 159 |
| 2-3 | Comparative | Inv-1 | 90 | 0 | 5.4 | 172 | — |

It can be seen from Table 3 that inventive Device 2-1 affords the combination of low voltage and high luminance with good stability. Comparative device 2-2 was fabricated with the same components as Device 2-1, except m-TDATA was used in place of nv-1. Although Device 2-2 does afford higher luminance relative to 2-1, the voltage is 2.1 V (33%) higher while the lifetime is 100 hours (39%) shorter than that of Device 2-1.

The efficiency of comparative Device 2-3, in which Inv-1 is in a layer contiguous to the light-emitting layer, has been drastically reduced by 93% relative to Device 1-1, where Inv-1 is not adjacent to the LEL. Due to the luminance being extremely low, the lifetime will be very long and hence, could not be properly measured. After 160 hours, the luminance had only dropped by 10%, however because of the low luminance this is not a useful device.

It is clear from this data that, when used in a layer with a strong electron acceptors, such as F₄TCNQ, the compounds of the present invention are superior compared to other compounds in the art. Furthermore, it is also clear that luminance is drastically reduced if a layer, containing only compounds of the present invention doped with strong electron acceptors, such as F₄TCNQ, is placed contiguous to the light-emitting layer.

### EXAMPLE 8

### The Fabrication of Device 3-1 and 3-2.

A conventional non-cascaded OLED, Device 3-1, was prepared by the following procedure. A 1.1 mm thick glass substrate coated with a transparent ITO conductive layer was cleaned and dried using a commercial glass. scrubber tool. The thickness of ITO is about 25 nm and the sheet resistance of the ITO is about 68 Ω/square. The ITO surface was subsequently treated with oxidative plasma to condition the surface as an anode. A layer of CFx, 1 nm thick, was deposited on the clean ITO surface as the HIL by decomposing CHF₃ gas in RF plasma treatment chamber. The substrate was then transferred into a vacuum deposition chamber for deposition of all other layers on top of the substrate. The following layers were deposited in the following sequence by sublimation from a heated boat under a vacuum of approximately 10-6 Torr:
(a) a 90 nm thick hole-transporting layer including NPB;
(b) a 30 nm light-emitting layer including AIQ₃ (98.7% by volume) as host and dopant L30 as the light emitting dopant (1.3% by volume);
(c) a 30 nm electron transport layer including AIQ₃ (99% by volume) and Li metal (1% by volume);
(d) a 210 nm cathode formed of a 20:1 atomic ratio of Mg and Ag.
   Following that the device was encapsulated in a nitrogen atmosphere along with calcium sulfate as a desiccant.

A cascaded or stacked OLED, Device 3-2, was prepared in the following manner. A 1.1 mm thick glass substrate coated with a transparent ITO conductive layer was cleaned and dried using a commercial glass scrubber tool. The thickness of ITO is about 25 nm and the sheet resistance of the ITO is about 68 K/square. The ITO surface was subsequently treated with oxidative plasma to condition the surface as an anode. A layer of CFx, 1 nm thick, was deposited on the clean ITO surface as the HIL by decomposing CHF₃ gas in RF plasma treatment chamber. The substrate was then transferred into a vacuum deposition chamber for deposition of all other layers on top of the substrate. The following layers were deposited in the following sequence by sublimation from a heated boat under a vacuum of approximately 10-6 Torr:
(a) a 90 nm thick hole-transporting layer including NPB;
(b) a 30 nm light-emitting layer including AIQ₃ (98.7% by volume) as host and dopant L30 as the light emitting dopant (1.3% by volume);
(c) an n-type doped organic layer, 30 nm thick, including Alq (99% by volume) and Li metal (1% by volume);
(d) a p-type doped organic layer, 60 nm thick, including Inv-1 (94% by volume) and F₄TCNQ (6% by volume);
(e) a 30 nm thick hole-transporting layer including NPB;
(f) a 30 nm light-emitting layer including AIQ₃ (98.7% by volume) as host and dopant L30 as the light emitting dopant (1.3% by volume);
(g) a 30 nm electron transport layer including AIQ₃ (99% by volume) and Li metal (1% by volume);
(h) a 210 nm cathode formed of a 20:1 atomic ratio of Mg and Ag. Following that the device was encapsulated in a nitrogen atmosphere along with calcium sulfate as a desiccant.

Devices 3-1 and 3-2 were tested for voltage and luminance at a constant current of 20 mA/cm . Device stability testing was measured at room temperature using AC current of 40 mA/cm , −14 V reverse bias. The devices were tested to T₇₀ which is the time taken for the initial luminance to fade 30%. Device performance results are reported in Table 4.

TABLE 4
The performance data for Device 3-1 and 3-2.

| | | | Cell | Power | |
|---|---|---|---|---|---|
| Device | | Voltage | Luminance | Efficiency | T₇₀ |
| Examples | Type | (V) | (cd/m²) | (lm/watt) | (Hours) |
| 3-1 | Comparative | 6.1 | 2088 | 5.4 | 183 |
| 3-2 | Inventive | 12.5 | 5057 | 6.3 | 102 |

It can be seen from Table 4 that, relative to the comparative Device 3-1, the inventive stacked OLED (Device 3-2) has just slightly more than twice the voltage, while the luminance is 2.4 times larger and the power efficiency is improved by 0.9 lm/W. The T₇₀ for the comparative device is 1.8 times greater than the inventive stacked OLED, however the inventive device will have a greater lifetime if the devices are faded from the same starting luminance, due to the fact that the inventive stacked OLED would be operating at a lower current density than the comparative device. From this data, it is clearly shown that a stacked OLED can be realized using the compounds of the present invention as p-type host materials.

The entire contents of the patents and other publications referred to in this specification are incorporated herein by reference. The invention has been described in detail with particular reference to certain preferred embodiments thereof, but it will be understood that variations and modifications can be effected within the spirit and scope of the invention.

### PARTS L1ST

101 Substrate

103 Anode

105 First Hole-Injecting layer (HIL)

106 Second Hole-Injecting layer (L2)

107 Hole-Transporting Layer (L1)

109 Light-Emitting layer (LEL)

111 Electron-Transporting layer (ETL)

113 Cathode

150 Power Source

160 Conductor

201 Substrate

203 Anode

205 Hole-Injecting layer (HIL)

207 First Hole-Transporting layer (HTL1)

208 First Light-Emitting layer (LEL1)

209 N-Type doped organic layer

210 P-Type doped organic layer

211 Second Hole-Transporting layer (HTL2)

212 Second Light-Emitting layer (LEL2)

213 Electron-Transporting layer (ETL)

214 Cathode

250 Power Source

260 Conductor

1. An OLED device comprising a cathode, an anode, and located therebetween a light emitting layer, the device comprising a further layer between the light-emitting layer and the anode but not contiguous to the light-emitting layer, the further layer containing a 2,6-diamino-substituted anthracene compound and containing a larger volume percentage of the 2,6-diamino-substituted anthracene compound than the layer contiguous to the light-emitting layer on the anode side.

2. The device of claim 1 wherein the layer contiguous to the light-emitting layer on the anode side is substantially free of a 2,6-diamino-substituted anthracene compound.

3. The device of claim 1 wherein the layer contiguous to the light-emitting layer on the anode side is free of a 2,6-diamino-substituted anthracene compound.

4. The device of claim 1 wherein the anthracene compound does not comprise a phenylene diamine group.

5. The device of claim 1 wherein the 2,6-diamino-substituted anthracene compound in the further layer has an oxidation potential between 0.60 V and 0.8 V.

6. The device of claim 1 wherein the further layer comprises a dopant possessing strong electron-withdrawing properties.

7. The device of claim 1 wherein the 2,6-diamino-substituted anthracene compound is represented by Formula (1): 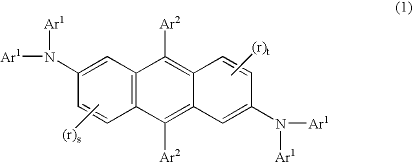
wherein:
each Ar¹ may be the same or different and each represents an independently selected aromatic group provided two adjacent Ar¹ groups may combine to form a ring;
each Ar² may be the same or different and each represents an independently selected aromatic group or N(Ar³)(Ar³), wherein each Ar³ may be the same or different and each represents an independently selected aromatic group;
each r represents an independently selected substituent, provided two adjacent r groups may combine to form a fused ring;
s and t are independently 0-3.

8. The device of claim 7 wherein Ar¹ does not contain an aromatic amine.

9. The device of claim 7 wherein Ar² and Ar³ do not contain an aromatic amine.

10. The device of claim 1 comprising the contiguous layer (L1) and the further layer (L2) which is adjacent to L1 on the anode side, wherein:
(a) layer L1 comprises a triarylamine derivative having an oxidation potential of 0.8-0.9 V; and
(b) layer L2 comprises a 2,6-diamino-substituted anthracene compound having an oxidation potential between 0.60-0.8 V.

11. The device of claim 1 comprising the contiguous (L1) and further layer (L2) which is adjacent to L1 on the anode side, and wherein:
(a) layer L1 comprises a triarylamine derivative; and
(b) layer L2 comprises a 2,6-diamino-substituted anthracene having an oxidation potential that is 0.05 to 0.4 V lower than the oxidation potential of the triarylamine derivative.

12. The device of claim 11 wherein layer L2 comprises a 2,6-diamino-substituted anthracene having an oxidation potential that is 0.1 to 0.3 V lower than the triarylamine derivative.

13. The device of claim 11 wherein the contiguous layer (L1) comprises a benzidine derivative.

14. The device of claim 11 wherein the contiguous layer (L1) comprises a compound represented by Formula (2): 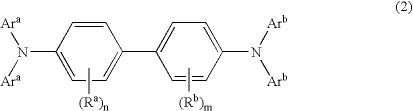
wherein:
each Ar^{a} and each Ar^{b} may be the same or different and each independently represents an aromatic group;
each Rₐ and each R_{b} may be the same or different and each independently represents a substituent group; and
n and m independently are 0-4.

15. The device of claim 1 including an additional layer between the further layer and the anode, wherein the additional layer includes a material of Formula (3): 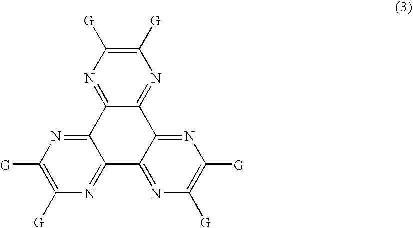
wherein:
each G may be the same or different and each G represents hydrogen or an electron withdrawing substituent, provided at least one electron withdrawing substituent is present.

16. The device of claim 1 including a second light-emitting layer between the first light-emitting layer and the anode.

17. The device of claim 1 which is a stacked OLED device comprising at least two light-emitting layers wherein the further layer is located between two light-emitting layers but not contiguous to a light-emitting layer.

18. The device of claim 17 wherein the further layer comprises a p-type dopant.

19. The device of claim 18 wherein the p-type dopant comprises a 7,7,8,8-tetracyanoquinodimethane compound or a derivative thereof.

20. An OLED device comprising a cathode, an anode, and located therebetween a light emitting layer, the device comprising a further layer between the light-emitting layer and the anode but not contiguous to the light-emitting layer, the further layer containing a 2,6-diamino-substituted anthracene compound and exhibiting an oxidation potential of at least 0.60 V vs. SCE.

21. An OLED device comprising a cathode, an anode, and located therebetween a light emitting layer, the device comprising a further layer between the light-emitting layer and the anode but not contiguous to the light-emitting layer, the further layer containing a 2,6-diamino-substituted anthracene compound including at least 9 aromatic rings.

22. A stacked organic electroluminescent device comprising: a) an anode; b) a cathode; c) a plurality of organic electroluminescent units disposed between the anode and the cathode, wherein the organic electroluminescent units comprise at least a hole-transporting layer, an electron-transporting layer, and an electroluminescent zone formed between the hole-transporting layer and the electron-transporting layer wherein the physical spacing between adjacent electroluminescent zones is more than 90 nm; and d) a connecting unit disposed between each adjacent organic electroluminescent unit, wherein the connecting unit comprises, in sequence, an n-type doped organic layer and a p-type doped organic layer forming a transparent p-n junction structure, and wherein at least one p-type doped organic layer comprises a 2,6-diamino-substituted anthracene compound.

23. The device of claim 22 wherein the 2,6-diamino-substituted anthracene compound is represented by Formula (1): 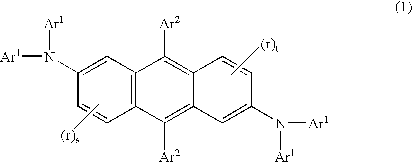
wherein:
each Ar¹ may be the same or different and each represents an independently selected aromatic group provided two adjacent Ar¹ groups may combine to form a ring;
each Ar² may be the same or different and each represents an independently selected aromatic group or N(Ar³)(Ar³), wherein each Ar³ may be the same or different and each represents an independently selected aromatic group;
each r represents an independently selected substituent, provided two adjacent r groups may combine to form a fused ring;
s and t are independently 0-3.
